(19) United States
(12) Patent Application Publication
(10) Pub. No.: US 2026/0182021 A1
(43) Pub. Date: Jun. 25, 2026

(54) SEMICONDUCTOR DEVICE INCLUDING SEPARATION PATTERN

(71) Applicant: SAMSUNG ELECTRONICS CO., LTD., Suwon-si (KR)

(72) Inventors: Sangwoo HAN, Suwon-si (KR); Kyuman Hwang, Suwon-si (KR); Jae Hyun Park, Suwon-si (KR); Juhun Park, Suwon-si (KR); Hongju Park, Suwon-si (KR)

(73) Assignee: SAMSUNG ELECTRONICS CO., LTD., Suwon-si (KR)

(21) Appl. No.: 19/259,124

(22) Filed: Jul. 3, 2025

(30) Foreign Application Priority Data
Dec. 20, 2024 (KR) 10-2024-0192591

(51) Int. Cl. H10D 84/85; H10D 84/01

(52) U.S. Cl. CPC H10D 84/856; H10D 84/0186; H10D 84/0188; H10D 84/851

(57) ABSTRACT

A semiconductor device includes a lower channel pattern and a lower source/drain pattern alternately disposed in a first direction on a substrate, an upper channel pattern on the lower channel pattern and an upper source/drain pattern on the lower source/drain pattern, gate patterns spaced apart in a second direction that crosses the first direction, and at least partially around the lower channel pattern and the upper channel pattern, a separation pattern at least partially penetrating the gate patterns in a third direction that crosses the first direction and the second direction, and a through via spaced apart by the separation pattern in the first direction, extending in the third direction, and coupled with at least one of the lower source/drain pattern or the upper source/drain pattern.

### CROSS-REFERENCE TO RELATED APPLICATIONS

This application claims priority under 35 U.S.C. § 119 to Korean Patent Application No. 10-2024-0192591, filed on Dec. 20, 2024, in the Korean Intellectual Property Office, the disclosure of which is incorporated by reference herein in its entirety.

### BACKGROUND

### 1. Field

The present disclosure relates generally to a semiconductor device, and more particularly, to a 3-dimensional (3D) semiconductor device including a separation pattern between a gate pattern and a through via.

### 2. Description of Related Art

As a demand for higher integration and/or high performance of semiconductor devices may continue to increase, 3-dimensional (3D) semiconductor device may be positioned as a core of a next-generation semiconductor technology. A 3D semiconductor device may attempt to provide improved electrical characteristics and/or integration of devices by designing a complex 3D structure in a vertical and/or a horizontal direction.

However, the 3D semiconductor device may need a multi-layer structure and/or a relatively complex pattern design, and as a result, a possible phenomenon of a short between metals may be a at least one cause of deterioration in the reliability and/or performance of the semiconductor device.

Short between metals may be caused by, but not limited to, a residual metallic material during a process, incomplete insulation layer formation, misalignment during metal deposition and patterning process, or the like. For example, as a spacing between metals in the 3D structure decreases, the risk of electric shorts may increase. Accordingly, there is a need for the development of technologies that may be efficiently integrated into a manufacturing process of 3D semiconductor devices while preventing and/or reducing the probability of a short between metal layers.

### SUMMARY

One or more example embodiments of the present disclosure provide a semiconductor device of which dispersion of a through via is reduced, when compared to related semiconductor devices, when forming the through via inside a gate cut pattern by forming a separation pattern before forming the gate cut pattern.

According to an aspect of the present disclosure, a semiconductor device includes a lower channel pattern and a lower source/drain pattern alternately disposed in a first direction on a substrate, an upper channel pattern on the lower channel pattern and an upper source/drain pattern on the lower source/drain pattern, gate patterns spaced apart in a second direction that crosses the first direction, and at least partially around the lower channel pattern and the upper channel pattern, a separation pattern at least partially penetrating the gate patterns in a third direction that crosses the first direction and the second direction, and a through via spaced apart by the separation pattern in the first direction, extending in the third direction, and coupled with at least one of the lower source/drain pattern or the upper source/drain pattern.

According to an aspect of the present disclosure, a semiconductor device includes an insulation substrate including a first side and a second side that face each other, a lower channel pattern and a lower source/drain pattern alternately disposed in a first direction on the first side, an upper channel pattern on the lower channel pattern and an upper source/drain pattern on the lower source/drain pattern, gate patterns spaced apart in a second direction that crosses the first direction, and at least partially around the lower channel pattern and the upper channel pattern, a separation pattern at least partially penetrating the gate patterns in a third direction that crosses the first direction and the second direction, a through via spaced apart by the separation pattern in the first direction, extending in the third direction, and coupled with at least one of the lower source/drain pattern or the upper source/drain pattern, and a lower wire structure on the second side and coupled with the through via.

According to an aspect of the present disclosure, a semiconductor device includes a lower channel pattern and a lower source/drain pattern alternately disposed in a first direction on a substrate, an upper channel pattern on the lower channel pattern and an upper source/drain pattern on the lower source/drain pattern, gate patterns spaced apart in a second direction that crosses the first direction, and at least partially around the lower channel pattern and the upper channel pattern, a gate cut pattern disposed between one of the lower source/drain pattern and one of the lower source/drain pattern and another one of the lower source/drain pattern and another one of the upper source/drain pattern in the second direction, a separation pattern at least partially penetrating the gate patterns in a third direction that crosses the first direction and the second direction, and a through via disposed within the gate cut pattern, extending in the third direction, and coupled with at least one of the lower source/drain pattern or the upper source/drain pattern. The separation pattern and the through via are alternately disposed along the first direction.

According to an aspect of the present disclosure, a manufacturing method of a semiconductor device includes preparing a substrate that includes a lower channel pattern and a lower source/drain pattern that are alternately disposed in a first direction, an upper channel pattern disposed on the lower channel pattern, and an upper source/drain pattern disposed on the lower source/drain pattern, forming a gate pattern that surrounds the lower channel pattern and the upper channel pattern and extends in a second direction crossing the first direction, forming a separation pattern that penetrate the gate pattern in a third direction that crosses the first direction and the second direction, and forming a through via that is spaced apart by the separation pattern in the first direction and connected with the lower source/drain pattern or the upper source/drain pattern by extending in the third direction.

In an embodiment, the manufacturing method of the semiconductor device may further include forming a gate cut pattern disposed between one of the lower source/drain pattern and another one of the lower source/drain pattern in the second direction and between one of the upper source/drain pattern and another one of the upper source/drain pattern in the second direction after forming the separation pattern.

In the manufacturing method of the semiconductor device, according to an embodiment, the through via may not be disposed between the gate patterns separated in the second direction by the separation pattern.

In the manufacturing method of the semiconductor device, according to an embodiment, the separation pattern may be formed before the gate cut pattern is formed.

In the manufacturing method of the semiconductor device, according to an embodiment, the forming of the gate cut pattern may include forming a recess between one of the lower channel pattern and the upper channel pattern and another one of the lower channel pattern and the upper channel pattern in the second direction, conformally forming an insulation liner layer on an inner wall of the recess, and forming a gap-fill insulation layer on the insulation liner layer.

In the manufacturing method of the semiconductor device, according to an embodiment, the gap-fill insulation layer may contain silicon oxide (SiO₂) and the insulation liner may contain silicon nitride.

In the manufacturing method of the semiconductor device, according to an embodiment, the forming of the through via may include forming a recess by etching the gap-fill insulation layer and filling the recess with a metal.

In an embodiment, the manufacturing method of the semiconductor device may further include forming an upper source/drain contact that may be connected to the upper source/drain pattern and forming an upper wire structure that may be connected with the upper source/drain pattern through the upper source/drain contact.

In an embodiment, the manufacturing method of the semiconductor device may further include removing the substrate and filling a region from which the substrate is removed with an insulating material, forming a lower source/drain contact connected with the lower source/drain pattern, and forming a connection portion extending from below the lower source/drain contact to below the through via.

In an embodiment, the manufacturing method of the semiconductor device may further include forming a lower wire structure connected with the lower source/drain contact and the connection portion.

According to the embodiments, by forming the separation pattern prior to forming the gate cut pattern, the dispersion of the through via may be reduced when forming the through via inside the gate cut pattern, when compared to a related semiconductor device.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a top plan view of a semiconductor device, according to an example embodiment;

FIG. 2 is a cross-sectional view of FIG. 1, taken along the lines A-A′ and D-D′, according to an example embodiment;

FIG. 3 is a cross-sectional view of FIG. 1, taken along the line B-B′, according to an example embodiment;

FIG. 4 is a cross-sectional view of FIG. 1, taken along the line C-C′, according to an example embodiment;

FIG. 5 is a cross-sectional view of FIG. 1, taken along the line E-E′, according to an example embodiment;

FIG. 6 is a cross-sectional view of FIG. 1, taken along the line A-A′, according to an example embodiment;

FIG. 7 is a cross-sectional view of FIG. 1, taken along the line B-B′, according to an example embodiment;

FIG. 8 is a top plan view of a semiconductor device, according to an example embodiment; and

FIGS. 8 to 45 are cross-sectional views that shows a process sequence according to a manufacturing method of a semiconductor device, according to an example embodiment.

### DETAILED DESCRIPTION

Hereinafter, various examples of the present disclosure are described with reference to the attached drawings such that a person having ordinary skill in the art to which the present disclosure pertains may implement the present disclosure. The present disclosure may be implemented in many different forms and is not limited to the examples described herein.

In order to describe the present disclosure, parts that may not be related to the description may be omitted, and the same reference symbols may be used for identical or similar components throughout the present disclosure.

In addition, the size and thickness of each component shown in the drawing may be arbitrarily shown for better understanding and ease of description, and thus, the present disclosure may not be necessarily limited to what is shown. In the drawings, the thickness of layers, films, panels, regions, or the like, may be exaggerated for clarity. In addition, in the drawing, for better understanding and ease of description, the thickness of some layers and regions may be exaggerated.

It is to be understood that when an element such as a layer, film, region, or substrate is referred to as being “on” another element, it may be directly on the other element or intervening elements may also be present. In contrast, when an element is referred to as being “directly on” another element, there are no intervening elements present. Further, throughout the present disclosure, the word “on” a target element is to be understood to be positioned above or below the target element, and may not necessarily be understood to be positioned “at an upper side” based on an opposite to gravity direction.

In addition, unless explicitly described to the contrary, the word “comprise”, and variations such as “comprises” or “comprising”, is to be understood to imply the inclusion of stated elements but not the exclusion of any other elements.

Further, throughout the present disclosure, the phrase “on a plane” may refer to viewing a target portion from the top, and the phrase “on a cross-section” may refer to viewing a cross-section formed by vertically cutting a target portion from the side.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In addition, throughout the present disclosure, the two (2) directions parallel to and intersecting an upper surface of a substrate may be referred to as a first direction D1 and a second direction D2, respectively, and a direction perpendicular to the upper surface of the substrate may be described as a third direction D3. For example, the first direction D1 and the second direction D2 may be orthogonal to each other.

In the drawing for a semiconductor device according to an example, a 3-dimensional stack field effect transistor (3D-SFET) structure may be illustrated as an example, but the present disclosure is not limited thereto. Depending on examples, a semiconductor device may include, but not be limited to, a gate all around (GAA) including nano wires or nano sheets, a multi-bridge channel field effect transistor (MBCFET™), a fin-type transistor (FinFET) including a channel region in a fin-type pattern shape, a tunneling transistor (FET), a 3D-SFET structure, and a complementary field effect transistor (CFET) structure.

As used herein, each of the terms “Al₂O₃”, “BaSrTi₂O₆”, “BaTiO₃”, “CoN”, “HfO₂”, “HfSiO₄”, “HfₓTa₁₋ₓO_{y}”, “HfZrO”, “La₂O₃”, “Li₂O”, “NiN”, “PbScTaO₃”, “PbZnNbO₃”, “PtN”, “SiBN”, “SiN”, “SiO₂”, “SiOBN”, “SiOC”, “SiOCN”, “SiON”, “SrTiO₃”, “TaN”, “Ta₂O₅”, “TiN”, “TiO₂”, “WN”, “ZrO₂”, “ZrSiO₄”, or the like may refer to a material made of elements included in each of the terms and is not a chemical formula representing a stoichiometric relationship.

Hereinafter, various embodiments of the present disclosure are described with reference to the accompanying drawings.

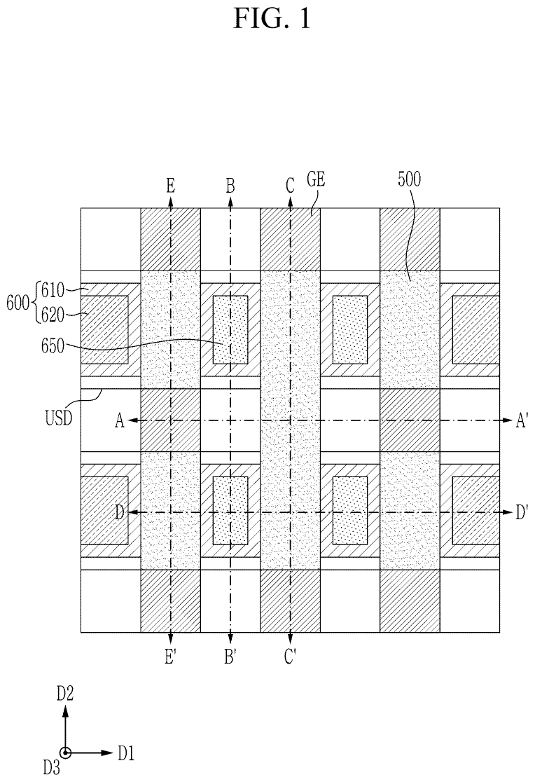

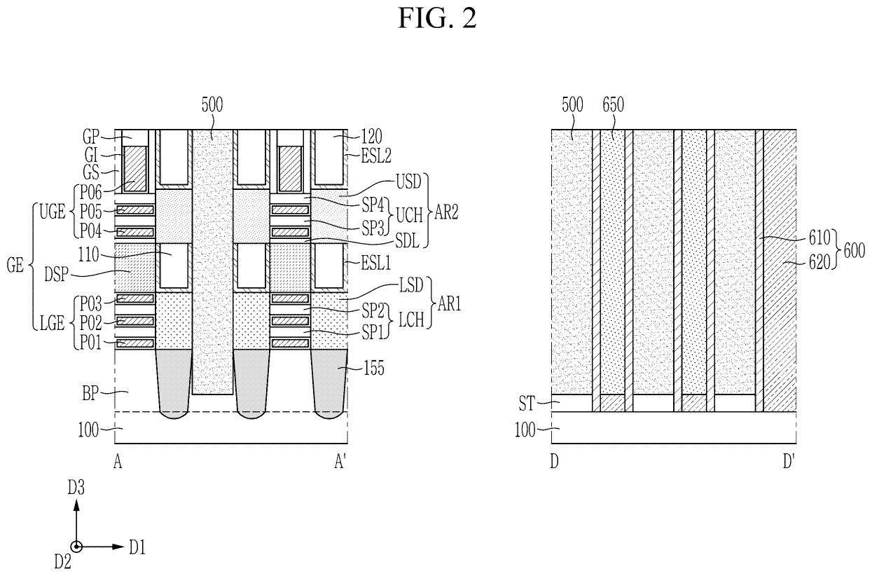

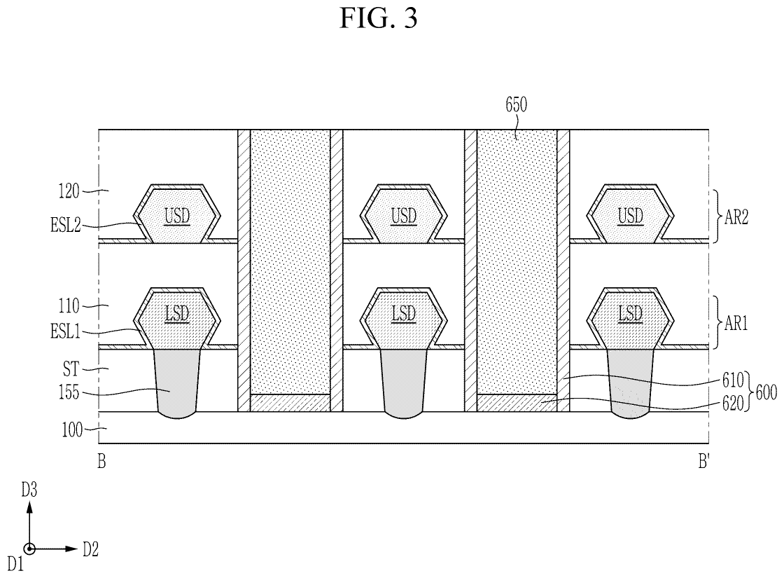

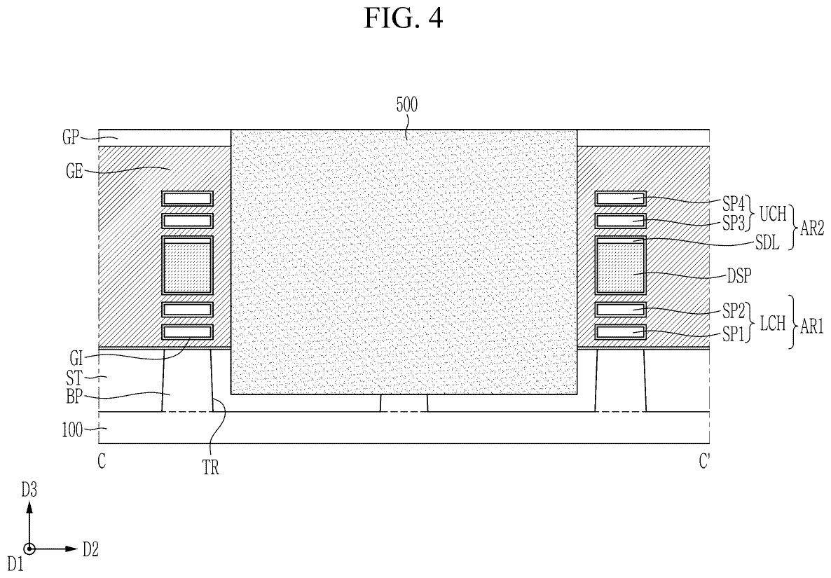

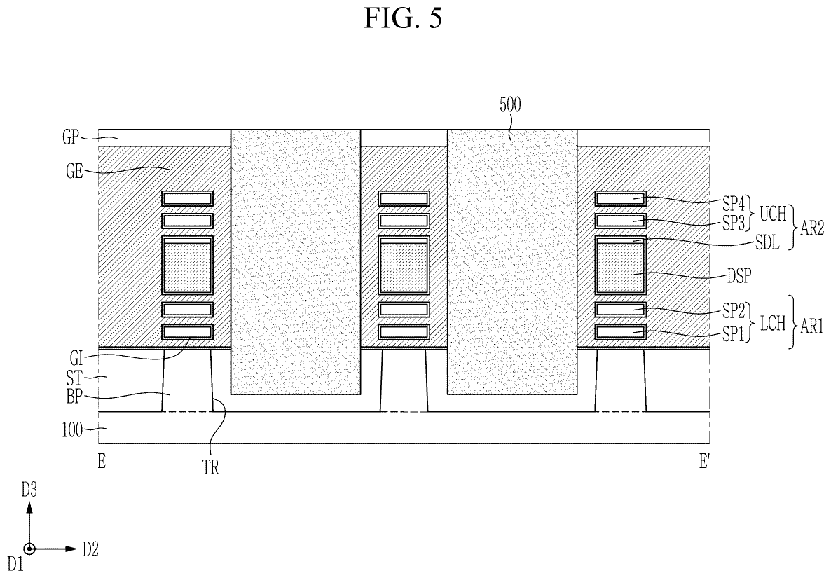

FIG. 1 is a top plan view of a semiconductor device, according to an example embodiment. FIG. 2 is a cross-sectional view of FIG. 1, taken along the lines A-A′ and D-D′, according to an example embodiment. FIG. 3 is a cross-sectional view of FIG. 1, taken along the line B-B′, according to an example embodiment. FIG. 4 is a cross-sectional view of FIG. 1, taken along the line C-C′, according to an example embodiment. FIG. 5 is a cross-sectional view of FIG. 1, taken along the line E-E′, according to an example embodiment.

Referring to FIG. 1, a top plan view of a semiconductor device including a gate pattern GE, an upper source/drain pattern USD, a separation pattern 500, a gate cut pattern 600, and a through via 650 is illustrated.

Referring to FIGS. 1 to 5, the semiconductor device may be a 3-dimensional (3D) semiconductor device (e.g., a stacked transistor). That is, transistors may be stacked in a third direction D3 in a cell region. For example, a single height cell (SHC) may be disposed between a first power wire and a second power wire, and the single height cell may include a first active region AR1 as a bottom tier, and a second active region AR2 may be stacked as a top tier on the first active region AR1.

For example, N-type metal-oxide semiconductor field-effect transistors (NMOSFETs) of the first active region AR1 may be disposed on the bottom pattern BP, and P-type metal-oxide semiconductor field-effect transistors (PMOSFETs) of the second active region AR2 may be disposed on the NMOSFETs. The first active region AR1 and the second active region AR2 may be separated from each other in the third direction D3.

That is, in the 3D semiconductor device, the first active region AR1 and the second active region AR2 may overlap in the third direction D3. Accordingly, the density of elements of the semiconductor device may be improved by reducing the area of a logic cell, when compared to a related semiconductor device.

In some embodiments, a peripheral area where transistors form a process core and/or an input/output (I/O) terminal may be disposed at the periphery of the cell region. That is, the peripheral area may be a core/peripheral region. For example, the peripheral area may include a long gate transistor (or long channel transistor) having a relatively long gate length (e.g., channel length). A transistor in the peripheral area may be operated with higher electric power than a transistor in the cell region. For example, the transistor in the cell region may be a single gate (SG) device, and the transistor in the peripheral area may be an extra gate (EG) device.

As shown in FIGS. 4 and 5, the bottom pattern BP may be defined by a trench TR disposed in the cell region. That is, the bottom pattern BP may be a portion protruded vertically from an upper end of the substrate 100. On a plane, the bottom pattern BP may have a bar shape that may be spaced in a second direction D2 and may extend in a first direction D1. The first active region AR1 and the second active region AR2 may be sequentially stacked on the bottom pattern BP.

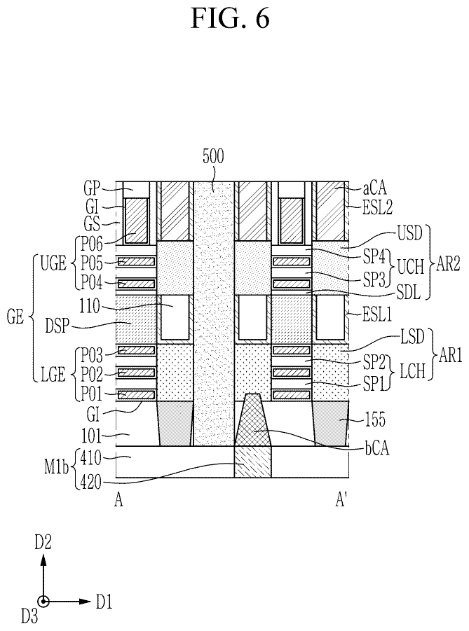

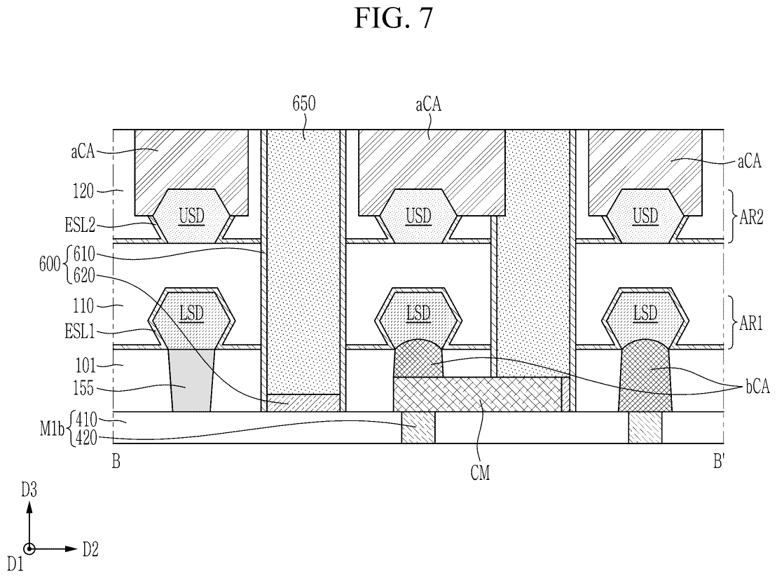

For example, the bottom pattern BP may include a semiconductor material such as, but not limited to, silicon (Si), germanium (Ge), or silicon germanium (SiGe), and may include silicon (Si), for example. In some examples, the bottom pattern BP may be replaced with an insulating material after removing the substrate 100 to form a lower source/drain contact bCA, as described with reference to FIGS. 6 and 7. For example, the bottom pattern BP may be replaced with a silicon oxide (SiO and accordingly, the bottom pattern BP may include a silicon oxide (SiO₂).

According to an example, a device isolation layer ST may fill the trench between the bottom patterns BP. For example, the device isolation layer ST may include a silicon oxide (SiO₂). An upper end of the device isolation layer ST may be coplanar with an upper end of the bottom pattern BP. Alternatively, a level of the upper end of the device isolation layer ST may be lower than a level of the upper end of the bottom pattern BP in the third direction D3. The device isolation layer ST may not cover a lower channel pattern LCH.

According to an example, the first active region AR1 including a lower channel pattern LCH and a lower source/drain pattern LSD may be disposed on the bottom pattern BP. The lower channel pattern LCH may be interposed between one lower source/drain pattern LSD and another lower source/drain pattern LSD spaced apart in the first direction D1. The lower channel pattern LCH may connect a pair of lower source/drain pattern LSD to each other. For example, the lower channel pattern LCH and the lower source/drain pattern LSD may be disposed alternately in the first direction D1.

According to an example, the lower channel pattern LCH may include a first semiconductor pattern SP1 and a second semiconductor pattern SP2 that may be stacked at a distance from each other in the third direction D3. However, embodiments of the present disclosure are not limited thereto, and the lower channel pattern LCH may include three (3) or more semiconductor patterns. Each of the first semiconductor pattern SP1 and the second semiconductor pattern SP2 may include silicon (Si), germanium (Ge), or silicon germanium (SiGe). For example, each of the first semiconductor pattern SP1 and the second semiconductor pattern SP2 may include crystalline silicon.

According to an example, the lower source/drain pattern LSD may be disposed on the upper end of the bottom pattern BP. The lower source/drain pattern LSD may be an epitaxial pattern formed by a selective epitaxial growth (SEG) process. For example, an upper end of the lower source/drain pattern LSD may be higher than an upper end of the second semiconductor pattern SP2 of the lower channel pattern LCH.

According to an example, the lower source/drain pattern LSD may be doped with an impurity to be of a first conductivity type. The first conductivity type may be an N-type or a P-type. For example, the first conductivity type may be an N-type. The lower source/drain pattern LSD may include silicon (Si) or silicon germanium (SiGe).

According to an example, a dummy source/drain pattern 155 may be disposed below the lower source/drain pattern LSD. The dummy source/drain pattern 155 may penetrate at least a part of the bottom pattern BP. For example, the dummy source/drain pattern 155 may be embedded in the bottom pattern BP. The dummy source/drain pattern 155 may be disposed below at least one lower source/drain pattern LSD among a plurality of lower source/drain patterns LSD.

For example, the dummy source/drain pattern 155 may include a substantially similar and/or the same material as the lower source/drain pattern LSD. For example, the dummy source/drain pattern 155 may include silicon (Si) or silicon germanium (SiGe), and may further include carbon (C), silicon (Si), germanium (Ge), or tin (Sn).

According to an example, a first layer interlayer stop film ESL1 may be disposed on the lower source/drain pattern LSD. For example, the first layer interlayer stop film ESL1 may cover the lower source/drain pattern LSD.

According to an example, a first interlayer insulating layer 110 may be disposed on the first layer interlayer stop film ESL1. The first interlayer insulating layer 110 may cover the lower source/drain pattern LSD.

For example, the first interlayer insulating layer 110 may include silicon oxide (SiO₂), silicon nitride (SiN), silicon oxynitride (SiON), or a low dielectric constant material.

According to an example, the first layer interlayer stop film ESL1 may include a material having etch selectivity with respect to the first interlayer insulating layer 110. For example, the first layer interlayer stop film ESL1 may include silicon nitride (SiN), silicon oxynitride (SiON), silicon oxycarbonitride (SiOCN), silicon boron nitride (SiBN), silicon boron oxynitride (SiOBN), or silicon carbide (SiOC).

According to an example, the second active region AR2 may be disposed on the first active region AR1. The second active region AR2 may include an upper channel pattern UCH and an upper source/drain pattern USD.

According to an example, the upper channel pattern UCH may be disposed on the lower channel pattern LCH. The upper source/drain pattern USD may be disposed on the lower source/drain pattern LSD. That is, the upper channel pattern UCH may overlap the lower channel pattern LCH in the third direction D3. The upper source/drain pattern USD may overlap the lower source/drain pattern LSD in the third direction D3. The upper channel pattern UCH may be disposed between one upper source/drain pattern USD and another upper source/drain pattern USD separated from it in the first direction D1. The upper channel pattern UCH may connect a pair of upper source/drain patterns USD. For example, the upper channel pattern UCH and the upper source/drain pattern USD may be disposed alternately in the first direction D1.

According to an example, the upper channel pattern UCH may include a third semiconductor pattern SP3 and a fourth semiconductor pattern SP4 that may be alternately stacked in the third direction D3. However, embodiments of the present disclosure are not limited thereto, and the upper channel pattern UCH may include three (3) of more semiconductor patterns. The third semiconductor pattern SP3 and the fourth semiconductor pattern SP4 of the upper channel pattern UCH may include a semiconductor material that may be substantially similar and/or the same as those of the above-described first and second semiconductor patterns SP1 and SP2 of the lower channel pattern LCH.

According to an example, at least one intermediate insulating structure DSP may be interposed between the lower channel pattern LCH and the upper channel pattern UCH disposed on the lower channel pattern LCH, and at least one dummy channel pattern SDL may be interposed between the first to fourth semiconductor patterns (e.g., a first semiconductor pattern SP1, a second semiconductor pattern SP2, a third semiconductor pattern SP3, and a fourth semiconductor pattern SP4).

For example, the intermediate insulating structure DSP may be disposed between the lower channel pattern LCH and the upper channel pattern UCH, and the dummy channel pattern SDL may be disposed between the intermediate insulating structure DSP and the third semiconductor pattern SP3 of the upper channel pattern UCH.

That is, the second semiconductor pattern SP2 of the lower channel pattern LCH, the third gate portion PO3 of the lower gate pattern LGE, the intermediate insulating structure DSP, a dummy channel pattern SDL, a fourth gate portion PO4 of an upper gate pattern UGE, and the third semiconductor pattern SP3 of the upper channel pattern UCH may be sequentially stacked in the third direction D3.

The intermediate insulating structure DSP may include a semiconductor material such as, but not limited to, silicon (Si), germanium (Ge), or silicon germanium (SiGe), or a silicon-based insulating material such as, but not limited to, silicon oxide (SiO₂), or silicon nitride (SiN). For example, the intermediate insulating structure DSP may include a silicon-based insulating material.

The dummy channel pattern SDL may include a semiconductor material such as, but not limited to, silicon (Si), germanium (Ge), or silicon germanium (SiGe), or a silicon-based insulating material such as, but not limited to, silicon oxide (SiO₂) or silicon nitride (SiN).

According to an example, the upper source/drain pattern USD may be disposed on an upper surface of the first interlayer insulating layer 110. The upper source/drain pattern USD may be an epitaxial pattern formed by the SEG process. For example, an upper end of the upper source/drain pattern USD may be higher than an upper end of the fourth semiconductor pattern SP4 of the upper channel pattern UCH.

The upper source/drain pattern USD may be impurity doped to have a second conductivity type. The second conductivity type may be different from the first conductivity type of the lower source/drain pattern LSD. For example, when the first conductivity type is N-type, the second conductivity type may be P-type. The upper source/drain pattern USD may include silicon germanium (SiGe) or silicon (Si).

According to an example, a second interlayer stop film ESL2 may be disposed on the upper source/drain pattern USD. For example, the second interlayer stop film ESL2 may cover the upper source/drain pattern USD.

The second interlayer stop film ESL2 may cover both sides of the upper source/drain pattern USD in the second direction D2. The second interlayer stop film ESL2 may not be disposed between the upper source/drain pattern USD and an upper source/drain contact aCA.

A second interlayer insulating layer 120 may be disposed on the second interlayer stop film ESL2. The second interlayer insulating layer 120 may cover the upper source/drain pattern USD.

For example, the second interlayer insulating layer 120 may include silicon oxide (SiO₂), silicon nitride (SiN), silicon oxynitride (SiON), or a low dielectric constant material.

The second interlayer stop film ESL2 may include a material having etch selectivity with respect to the second interlayer insulating layer 120. The second interlayer stop film ESL2 may include, for example, silicon nitride (SiN), silicon oxynitride (SiON), silicon oxycarbonitride (SiOCN), silicon boron nitride (SiBN), silicon boron oxynitride (SiOBN), silicon carbide (SiOC), or a combination thereof.

According to an example, a gate pattern GE may be disposed on the lower channel pattern LCH and the upper channel pattern UCH. For example, at least a portion of the gate pattern GE may be replaced with the separation pattern 500. That is, the separation pattern 500 may be formed at a position where the gate pattern GE may be removed after removing at least a part of the gate pattern GE.

Accordingly, any one gate pattern GE may be separated from another gate pattern GE in the second direction D2 by the separation pattern 500. That is, the separation pattern 500 may penetrate the lower gate pattern LGE and the upper gate pattern UGE of the gate pattern GE. Accordingly, the connection of the gate pattern GE may be cut by the separation pattern 500.

A separation distance D2 of the gate pattern GE along the second direction may be substantially similar and/or the same as a width of the separation pattern 500 along the second direction D2. For example, a width of the separation pattern 500 in the second direction D2 may be smaller than or equal to a distance between one lower channel pattern LCH and one upper channel pattern UCH and another lower channel pattern LCH and another upper channel pattern UCH.

A part of the gate pattern GE may overlap the stacked lower channel pattern LCH and upper channel pattern UCH in the third direction D3. The gate pattern GE may extend to a gate capping pattern GP, from an upper end of the device isolation layer ST or an upper end of the bottom pattern BP in the third direction D3. The gate pattern GE may extend to the upper channel pattern UCH of the second active region AR2 from the lower channel pattern LCH of the first active region AR1 in the third direction D3. That is, the gate pattern GE may extend in the third direction D3 from the first semiconductor pattern SP1 at the bottom to the fourth semiconductor pattern SP4 at the top.

The gate pattern GE may be disposed on an upper end, a bottom surface, and opposite side surfaces of each of the first semiconductor pattern SP1, the second semiconductor pattern SP2, the third semiconductor pattern SP3, and the fourth semiconductor pattern SP4. That is, in the logic cell, the gate pattern GE may include a 3D field effect transistor (e.g., a multi-bridge channel field effect transistor (MBCFET™) or a gate-all-around field effect transistor (GAAFET)) that surrounds a channel 3-dimensionally.

According to an example, the gate pattern GE may include a lower gate pattern LGE and an upper gate pattern UGE that may be sequentially stacked. The lower gate pattern LGE and the upper gate pattern UGE may overlap each other in the third direction D3. The lower gate pattern LGE and the upper gate pattern UGE may be connected with each other. That is, the gate pattern GE may be a common gate electrode to which the lower gate pattern LGE on the lower channel pattern LCH and the upper gate pattern UGE on the upper channel pattern UCH may be connected.

At least a part of the gate pattern GE may be disposed above and below a structure in which the lower channel pattern LCH, the intermediate insulating structure DSP, the dummy channel pattern SDL, and the upper channel pattern UCH may be alternately stacked. Another part of the gate pattern GE may be formed to cover opposite side surfaces of a structure in which the lower channel pattern LCH, the intermediate insulating structure DSP, the dummy channel pattern SDL, and the upper channel pattern UCH may be alternately stacked. In this case, four (4) sides of each of the lower channel patterns LCH and upper channel patterns UCH may be surrounded by the gate pattern GE.

According to an example, the lower gate pattern LGE may include a first gate portion P1 disposed between the bottom pattern BP and the first semiconductor pattern SP1, a second gate portion PO2 disposed between the first semiconductor pattern SP1 and the second semiconductor pattern SP2, and a third gate portion PO3 disposed between the second semiconductor pattern SP2 and the intermediate insulating structure DSP.

The upper gate pattern UGE may include a fourth gate portion PO4 disposed between the dummy channel pattern SDL and the third semiconductor pattern SP3, a fifth gate portion PO5 disposed between the third semiconductor pattern SP3 and the fourth semiconductor pattern SP4, and a sixth gate portion PO6 disposed on the fourth semiconductor pattern SP4.

For example, the lower gate pattern LGE may include a first work function metal pattern disposed on the first and second semiconductor patterns SP1 and SP2. The upper gate pattern UGE may include a second work function metal pattern disposed on the third and fourth semiconductor patterns SP3 and SP4. The first work function metal pattern and the second work function metal pattern each may include a metal including titanium (Ti), tantalum (Ta), aluminum (Al), tungsten (W), molybdenum (Mo), or a combination thereof, and nitrogen (N). The first work function metal pattern and the second work function metal pattern may have different work functions. The gate pattern GE may include a low-resistivity metal, such as, but not limited to, tungsten (W), ruthenium (Ru), aluminum (Al), titanium (Ti), tantalum (Ta), or a combination thereof on first work function metal pattern and the second work function metal pattern.

A gate insulation layer GI may be disposed between the gate pattern GE and the first semiconductor pattern SP1 to the fourth semiconductor pattern SP4. The gate insulation layer may include a silicon oxide (SiO₂), a silicon oxynitride (SiON) layer, a high dielectric layer, or a combination thereof. For example, the gate insulation layer GI may include silicon oxide (SiO₂) directly covering a surface of the first semiconductor pattern SP1 to a surface of the fourth semiconductor pattern SP4 and a high dielectric layer disposed on the silicon oxide (SiO₂). That is, the gate insulation layer GI may include multi-layers of silicon oxide (SiO₂) and a high dielectric layer.

The high dielectric layer may include a high dielectric constant material having a higher dielectric constant than silicon oxide (SiO₂). For example, the high dielectric constant material may include hafnium oxide (HfO₂), hafnium silicon oxide (HfSiO₄), hafnium zirconium oxide (HfZrO), hafnium tantalum oxide (HfₓTa₁₋ₓO_{y}), lanthanum oxide (La₂O₃), zirconium oxide (ZrO₂), zirconium silicon oxide (ZrSiO₄), tantalum oxide (Ta₂O₅), titanium oxide (TiO₂), barium strontium titanium oxide (BaSrTi₂O₆), barium titanium oxide (BaTiO₃), strontium titanium oxide (SrTiO₃), lithium oxide (Li₂O), aluminum oxide (Al₂O₃), lead scandium tantalum oxide (PbScTaO₃), lead zinc niobate (PbZnNbO₃), or a combination thereof.

In some embodiments, a gate inner spacer may be disposed between the gate pattern GE and the lower source/drain pattern LSD. A gate inner spacer may be disposed between the gate pattern GE and the upper source/drain pattern USD. For example, the gate inner spacer may be disposed between the first to third gate portions (e.g., a first gate portion PO1, a second gate portion PO2, and a third gate portion PO3) of the lower gate pattern LGE and the lower source/drain pattern LSD, and may be disposed between the fourth and fifth gate portions PO4 and PO5 of the upper gate pattern UGE and the upper source/drain pattern USD.

For example, on one cross-section, the gate inner spacer may be disposed on opposite sides of each of the first to fifth gate portions PO1 to PO5 in the first direction D1.

For example, the gate inner spacer may include a low dielectric constant material. The low dielectric constant material may include silicon oxide (SiO₂), or a material having a lower dielectric constant than silicon oxide (SiO₂). For example, the low dielectric constant material may include silicon oxide (SiO₂), fluorine (F) or carbon (C)-doped silicon oxide, porous silicon oxide, or organic polymer dielectric.

A pair of gate spacers GS may be arranged on opposite side surfaces of each of the sixth gate portion PO6 of the gate pattern GE in the first direction D1.

Upper end portions of the gate spacers GS may be higher than an upper end portion of the gate pattern GE. The upper end portions of the gate spacers GS may be coplanar with an upper end portion of the second interlayer insulating layer 120.

The gate spacers GS may include silicon carbon nitride (SiCN), silicon oxycarbonitride (SiOCN), silicon nitride (SiN), or a combination thereof. For example, the gate spacers GS may include multi-layers each including silicon carbon nitride (SiCN), silicon oxycarbonitride (SiOCN), silicon nitride (SiN), or a combination thereof.

The gate capping pattern GP may be disposed on the upper end portion of the gate pattern GE. For example, the gate capping pattern GP may include silicon oxynitride (SiON), silicon carbon nitride (SiCN), silicon oxycarbonitride (SiOCN), silicon nitride (SiN), or a combination thereof.

According to an example, the separation pattern 500 may be formed at a position where the gate pattern GE may be removed after at least a portion of the gate pattern GE may be removed before a gate cutting pattern 600 may be formed. Accordingly, a width of the separation pattern 500 in the first direction D1 may be similar to or substantially the same as a width of the gate pattern GE in the first direction D1.

According to an example, the separation pattern 500 may extend in the second direction D2. The separation pattern 500 may extend from one gate pattern GE in the second direction D2 to another gate pattern GE separated in the second direction D2. For example, as shown in FIG. 4, separation pattern 500 may have a bar shape that may be separated in the first direction D1 and extends in the second direction D2. Alternatively, for example, as shown in FIG. 5, the separation pattern 500 may be separated in the first direction D1 and also in the second direction D2 with the lower channel pattern LCH and the upper channel pattern UCH therebetween.

According to an example, as the separation pattern 500 may be formed at the position where the gate pattern GE may be removed, the separation pattern 500 and the gate pattern GE may be disposed between one gate cut pattern 600 and another gate cut pattern 600 spaced apart from the one gate cut pattern 600 in the first direction D1.

According to an example, the separation pattern 500 may be disposed on the bottom pattern BP.

However, a level of an upper end portion of the bottom pattern BP disposed below the separation pattern 500 in the third direction D3 may be lower than a level of an upper end portion of the lower pattern BP disposed below the gate pattern GE. Accordingly, a level of a lower end portion of the separation pattern 500 in the third direction D3 may be lower than a level of a lower end portion of the gate pattern GE.

According to an example, the separation pattern 500 may extend along the third direction D3. For example, the separation pattern 500 may extend to a higher level than the upper end portion of the gate pattern GE from the lower end portion of the gate pattern GE along the third direction D3. The separation pattern 500 may extend from a level lower than the lower end portion of the gate pattern GE to the upper end portion of the gate capping pattern GP along the third direction D3. That is, the lower end portion of the separation pattern 500 may be disposed closer to the lower end portion of the bottom pattern BP in the third direction D3 than to the lower end portion of the gate pattern GE.

For example, the level of the lower end portion of the separation pattern 500 in the third direction D3 may be lower than the level of the upper end portion of the bottom pattern BP, lower than the lower end portion of the lower source/drain pattern LSD, higher than a level of the lower end portion of the dummy source/drain pattern 155, higher than a level of the lower end of the gate cut pattern 600, and lower than a level of the lower end portion of a through via 650.

As used herein, the level of the lower end portion of the separation pattern 500 along the third direction D3 may refer to the shortest distance to the lower end portion of the separation pattern 500 along the third direction D3, using the lower end portion of the bottom pattern BP as a reference.

For example, the separation pattern 500 may include an insulating material. For example, the separation pattern 500 may include silicon oxide (SiO₂), silicon nitride (SiN), silicon oxynitride (SiON), a high dielectric constant (high-k) material having a higher dielectric constant than silicon oxide (SiO₂), or a combination thereof, and may include silicon nitride (SiN).

According to an example, in one plane (e.g., FIG. 1), the gate cut pattern 600 may be spaced in the second direction D2. As described above, since at least a portion of the gate pattern GE may be replaced with the separation pattern 500, the gate cut pattern 600 may also be separated in the first direction D1 by the separation pattern 500.

According to an example, the level of the lower end portion of the gate cut pattern 600 along the third direction D3 may be lower than the level of the lower end portion of the separation pattern 500 may be lower than the level of the lower end portion of the through via 650, and may be higher than or equal to the level of the lower end portion of the dummy source/drain pattern 155. The lower end portion of the gate cut pattern 600 may contact the upper end portion of the substrate 100.

As used herein, the level of the lower end portion of the gate cut pattern 600 along the third direction D3 may refer to the shortest distance to the lower end portion of the gate cut pattern 600 along the third direction D3, using the upper end portion of the substrate 100 as a reference.

According to an example, the gate cut pattern 600 may be disposed between one lower source/drain pattern LSD and another lower source/drain pattern LSD spaced apart in the second direction D2. The gate cut pattern 600 may be disposed between any one upper source/drain pattern USD and the upper source/drain pattern USD.

In addition, the gate cut pattern 600 may be disposed between the dummy source/drain pattern 155 and another dummy source/drain pattern 155 spaced apart in the second direction D2.

Since the gate cut pattern 600 may be formed after the separation pattern 500, which penetrates the gate pattern GE in the third direction D3. may be formed, the gate cut pattern 600 may not be disposed between the gate patterns GE in the second direction D2. For example, the gate cut pattern 600 may not be disposed between one gate pattern GE and another gate pattern GE spaced apart in the second direction D2.

For example, the gate cut pattern 600 may include a gap-fill insulation layer 620 and an insulation liner 610.

The gap-fill insulation layer 620 may be disposed to fill an inner space of the gate cut pattern 600. The gap-fill insulation layer 620 may be disposed approximately at a center of the gate cut pattern 600 in the second direction D2.

As described below, since the separation pattern 500 may be formed before the gate cut pattern 600 may be formed, the insulation liner 610 may be configured to surround four (4) sides of the gap-fill insulation layer 620. In addition, the insulation liner 610 may be formed to surround four (4) sides of the through via 650 described below.

In some examples, a boundary between the insulation liner 610 and the separation pattern 500 may not be visible. For example, when the insulation liner 610 and the separation pattern 500 include the same and/or a substantially similar material, the boundary between the insulation liner 610 and the separation pattern 500 may not be visible.

In some examples, the insulation liner 610 may be disposed at opposite sides of the gap-fill insulation layer 620. For example, the insulation liner 610 may be separately disposed on opposite sides of the gap-fill insulation layer 620 in the second direction D2.

The gate cut pattern 600 may include an insulating material. For example, the gate cut pattern 600 may include silicon oxide (SiO₂), silicon nitride (SiN), silicon oxynitride (SiON), a high dielectric constant (high-k) material having a higher dielectric constant than silicon oxide (SiO₂), or a combination thereof, and may include silicon nitride (SiN).

For example, the gap-fill insulation layer 620 and the insulation liner 610 that form the gate cut pattern 600 may include different materials. For example, the gap-fill insulation layer 620 may include silicon oxide (SiO₂) and the insulation liner 610 may include silicon nitride (SiN). However, this is only one example, and the materials of the gap-fill insulation layer 620 and the insulation liner 610 may vary.

According to an example, the through via 650 may be disposed in the gate cut pattern 600. The through via 650 may extend in the third direction D3, and thus, may be inserted into the entire gate cut pattern 600 or at least part of the gate cut pattern 600.

For example, the through via 650 may extend in the third direction D3 from a level higher than a lower end portion of the gate cut pattern 600 to a level lower than or substantially the same as an upper end portion of the gate cut pattern 600. That is, the lower end portion of the through via 650 may be disposed further from the lower end portion of the bottom pattern BP than the lower end portion of the gate cut pattern 600 in the third direction D3.

In addition, a level of the lower end portion of the through via 650 in the third direction D3 may be higher than the level of the upper end portion of the bottom pattern BP, may be higher than a level of the lower end portion of the gate cut pattern 600, may be higher than a level of the lower end portion of the separation pattern 500, and may be higher than a level of the lower end portion of the dummy source/drain pattern 155.

As used herein, the level of the lower end portion of the through via 650 along the third direction D3 may refer to the shortest distance to the lower end portion of the through via 650 along the third direction D3, using the lower end portion of the bottom pattern BP as a reference.

According to an example, the through via 650 may be spaced apart in the second direction D2. As described above, as at least a part of the gate pattern GE may be replaced with the separation pattern 500, the through via 650 may be separated by the separation pattern 500 in the first direction D1. According to an example, since the through via 650 may be separated in the first direction D1 by the separation pattern 500 that penetrates the gate pattern GE in the third direction D3, the through via 650 may not penetrate the gate pattern GE.

According to an example, the through via 650 may be disposed approximately at a center of the gate cut pattern 600 in the second direction D2. The insulation liner 610 of the gate cut pattern 600 may be configured to surround four (4) sides of the through via 650. That is, the insulation liner 610 may be in contact with the through via 650 in the first direction D1 and the second direction D2. However, embodiments of the present disclosure are not limited thereto, and, for example, the gap-fill insulation layer 620 of the gate cut pattern 600 may be disposed to fill an internal space between the through via 650 and the insulation liner 610.

In some examples, the through via 650 may contain a conductive pattern and a barrier pattern that may surround the conductive pattern. For example, the conductive pattern may include a metal containing aluminum (Al), copper (Cu), tungsten (W), molybdenum (Mo), or a combination thereof. The barrier pattern may cover side walls and a bottom surface of the conductive pattern. The barrier pattern may include a metal layer or a metal nitride layer. The metal layer may include titanium (Ti), tantalum (Ta), tungsten (W), nickel (Ni), cobalt (Co), platinum (Pt), or a combination thereof. The metal nitride layer may include a titanium nitride layer (TiN), a tantalum nitride layer (TaN), a tungsten nitride layer (WN), a nickel nitride layer (NiN), a cobalt nitride layer (CoN), a platinum nitride layer (PtN), or a combination thereof.

The insulation liner 610 may be disposed on both sides of the through via 650 in the first direction D1 and the second direction D2, and the gap-fill insulation layer may be disposed below the through via 650. The through via 650 may be disposed inside the gate cut pattern 600, and the gap-fill insulation layer 620 fills inside the gate cut pattern 600, and therefore a bottom surface of the through via 650 may be in contact with the gap-fill insulation layer 620.

When the gate cut pattern 600 includes the gap-fill insulation layer 620 containing oxide and the insulation liner 610 containing nitride, etching of the gate cut pattern 600 for forming the through via 650 inside the gate cut pattern 600 may be smoothly carried out.

As described above, the semiconductor device, according to the present disclosure, may have a through via 650 that may not overlap with the gate pattern GE in the second direction D2. Accordingly, a short may be prevented from occurring between the through via 650 and the gate pattern GE.

FIG. 6 is a cross-sectional view of FIG. 1, taken along the line A-A′, according to an example embodiment. FIG. 7 is a cross-sectional view of FIG. 1, taken along the line B-B′, according to an example embodiment.

A semiconductor device shown in FIGS. 6 and 7 may include components that may be similar to and/or the same as those of the semiconductor device described with reference to FIGS. 1 to 5. However, the semiconductor device in the present embodiment may be different from that illustrated in FIGS. 1 to 5 in that a substrate 100 may be removed and then replaced with an insulating material to form a lower source/drain contact bCA. Consequently, overlapping content from the above may be briefly described and/or omitted for the sake of brevity, and differences may be described.

Referring to FIGS. 6 and 7, a semiconductor device according to an example may include an insulation substrate 101. In particular, the substrate 100 may be removed and replaced with the insulation substrate 101 to form the lower source/drain contact bCA. For example, the insulation substrate 101 may include silicon oxide (SiO₂).

According to an example, when removing substrate 100 to form the lower source/drain contact bCA, the substrate 100 may be removed until the dummy source/drain pattern 155 may be exposed. Accordingly, a lower end portion of the dummy source/drain pattern 155 may have a flat shape and may be in contact with the lower wire structure M1b.

According to an example, a separation pattern 500 may be disposed between one upper source/drain contact aCA and another upper source/drain contact aCA spaced apart in the first direction D1. In addition, the separation pattern 500 may be disposed between one lower source/drain contact bCA and another lower source/drain contact bCA spaced apart in the first direction D1. Alternatively, the separation pattern 500 may be disposed between the lower source/drain contact bCA and a dummy source/drain pattern 155 spaced apart from the lower source/drain contact bCA in the first direction D1. Alternatively, the separation pattern 500 may be disposed between one dummy source/drain pattern 155 and another dummy source/drain pattern 155 spaced apart in the first direction D1.

According to an example, the separation pattern 500 may be separated from a lower wire structure M1b in the third direction D3. That is, a lower end portion of the separation pattern 500 may not contact an upper end portion of the lower wire structure M1b. The insulation substrate 101 may be disposed between the separation pattern 500 and the lower wire structure M1b.

According to an example, a lower end portion of the gate cut pattern 600 may be in contact with an upper end portion of the lower wire structure M1b. In addition, the gate cut pattern 600 may be disposed between one lower source/drain contact bCA and another lower source/drain contact bCA spaced apart in the second direction D2. Alternatively, the gate cut pattern 600 may be disposed between one lower source/drain contact bCA in the second direction D2 and the dummy source/drain pattern 155 spaced apart in the second direction D2. Alternatively, the gate cut pattern 600 may be disposed between one dummy source/drain pattern 155 in the second direction D2 and another dummy source/drain pattern 155 spaced apart in the second direction D2.

According to an example, an upper portion of a through via 650 may be connected to the upper source/drain contact aCA and a lower portion of the through via 650 may be connected to the lower source/drain contact bCA. Accordingly, the through via 650 may be connected between the upper source/drain contact aCA and the lower source/drain contact bCA. In addition, the through via 650 may be connected to the lower wire structure M1b.

The lower end portion of the through via 650 may not be in contact with an upper end portion of the lower wire structure M1b. A gap-fill insulation layer 620 of the gate cut pattern 600 may be disposed between the through via 650 and the lower wire structure M1b. A connection portion CM may be disposed between the through via 650 and the lower wire structure M1b.

According to an example, the upper source/drain contact aCA may penetrate the second interlayer insulating layer 120 and thus may be electrically connected with the upper source/drain pattern USD. In addition, in some embodiments, the upper gate contact may penetrate the second interlayer insulating layer 120 and the gate capping pattern GP and thus may be electrically connected with the gate pattern GE.

The upper source/drain contact aCA may extend in the second direction D2 and thus may be connected with the through via 650. A part of the upper source/drain contact aCA may be inserted into the gate cut pattern 600. That is, a part of the upper source/drain contact aCA may overlap a part of the gate cut pattern 600 in the third direction D3. For example, a part of the upper source/drain contact ACA may be positioned over the gap-fill insulation layer 620 through the insulation liner 610 of the gate cut pattern 600. For example, the upper source/drain contact aCA may be in contact with the through via 650. Accordingly, the upper source/drain contact aCA may be connected with the lower source/drain contact bCA through the through via 650.

In some embodiments, the upper source/drain contact aCA may include a conductive pattern and a barrier pattern surrounding the conductive pattern. For example, the conductive pattern may include aluminum (Al), copper (Cu), tungsten (W), molybdenum (Mo), or a combination thereof. The barrier pattern may cover side surfaces and a bottom surface of the conductive pattern. The barrier pattern may include a metal layer or a metal nitride layer. The metal layer may include titanium (Ti), tantalum (Ta), tungsten (W), nickel (Ni), cobalt (Co), platinum (Pt), or a combination thereof. The metal nitride layer may include a titanium nitride layer (TiN), a tantalum nitride layer (TaN), a tungsten nitride layer (WN), a nickel nitride layer (NiN), a cobalt nitride layer (CoN), a platinum nitride layer (PtN), or a combination thereof.

In some embodiments, the upper interlayer insulating layer may be disposed on the upper source/drain contact aCA and cover the upper source/drain contact aCA.

According to an example, the lower source/drain contact bCA may be disposed below the lower source/drain pattern LSD and may be electrically connected with the lower source/drain pattern LSD. For example, the lower source/drain contact bCA may penetrate the insulation substrate 101 and may be electrically connected to the lower source/drain pattern LSD.

According to an example, the connection portion CM may be disposed below the lower source/drain contact bCA and the through via 650. The connection portion CM may be extended in the second direction D2 to connect the lower source/drain contact bCA and the through via 650. Accordingly, the lower source/drain contact bCA may be connected to the upper source/drain contact aCA through the connection portion CM and the through via 650.

According to an example, the connection portion CM may be disposed between the lower wire structure M1b, the lower source/drain contact bCA, and the through via 650 in the third direction D3. A part of the connection portion CM may be inserted into the gate cut pattern 600. That is, a part of the connection portion CM may overlap a part of the gate cut pattern 600 in the third direction D3. For example, a part of the connection portion CM may pass through the insulation liner 610 of the gate cut pattern 600 and may be connected with the through via 650.

In addition, a lower gate contact may be disposed below the lower gate pattern LGE and electrically connected with the lower gate pattern LGE. For example, the lower gate contact may be electrically connected to the lower gate pattern LGE through the insulation substrate 101 or a device isolation layer ST.

In some embodiments, each of the lower source/drain contact bCA and the lower gate contact may include a conductive pattern and a barrier pattern surrounding the conductive pattern. For example, the conductive pattern may include aluminum (Al), copper (Cu), tungsten (W), molybdenum (Mo), or a combination thereof. The barrier pattern may cover side surfaces and a bottom surface of the conductive pattern. The barrier pattern may include a metal layer or a metal nitride layer. The metal layer may include titanium (Ti), tantalum (Ta), tungsten (W), nickel (Ni), cobalt (Co), platinum (Pt), or a combination thereof. The metal nitride layer may include a titanium nitride layer (TiN), a tantalum nitride layer (TaN), a tungsten nitride layer (WN), a nickel nitride layer (NiN), a cobalt nitride layer (CoN), a platinum nitride layer (PtN), or a combination thereof.

According to an example, the lower wire structure M1b may be disposed below the lower source/drain contact bCA and the lower gate contact.

The lower wire structure M1b may include a lower interlayer insulating layer 410 and a lower metal layer 420 disposed in the lower interlayer insulating layer 410.

The lower interlayer insulating layer 410 may be disposed below the lower source/drain contact bCA and the lower gate contact, and may cover the insulation substrate 101, the device isolation layer ST, the lower source/drain contact bCA, the lower gate contact, the dummy source/drain pattern 155, the connection portion CM, and a lower end portion of the separation pattern 500.

The lower interlayer insulating layer 410 may include an insulating material, and for example, may include silicon oxide (SiO₂), silicon nitride (SiN), silicon oxynitride (SiON), a low-dielectric material, or a combination thereof.

The lower metal layer 420 may be disposed in the lower interlayer insulating layer 410. The lower metal layer 420 may include lower power wires, lower wires, and lower vias. The lower vias may be disposed on the lower power wires and the lower wires. The lower vias may be interposed between the lower source/drain contact bCA, the lower gate contact, and the connection portion CM, and the lower power wires and lower wires, respectively.

The lower power wires and the lower wires of the lower metal layer 420 may contain the same or different conductive materials. For example, the lower power wires and the lower wires may include aluminum (Al), copper (Cu), tungsten (W), molybdenum (Mo), cobalt (Co), or a combination thereof.

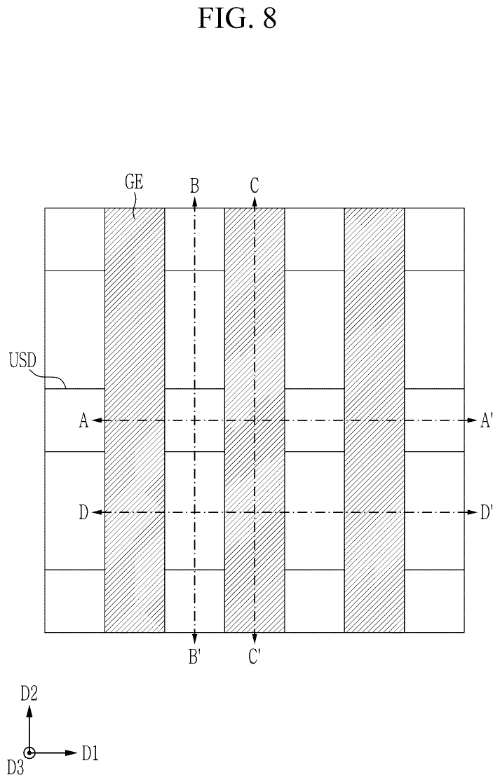

Referring to FIGS. 8 to 45, a method for manufacturing a semiconductor device according to an example is described. In addition, FIGS. 1 to 7 described above may also be referred to together with the description of FIGS. 8 to 45.

FIGS. 8 to 45 are cross-sectional views of a process order of a manufacturing method of a semiconductor device, according to an example embodiment.

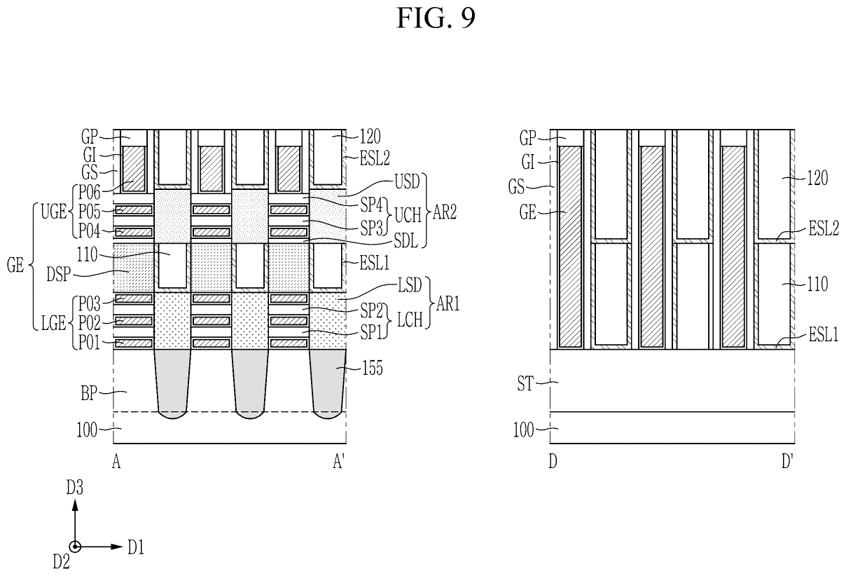

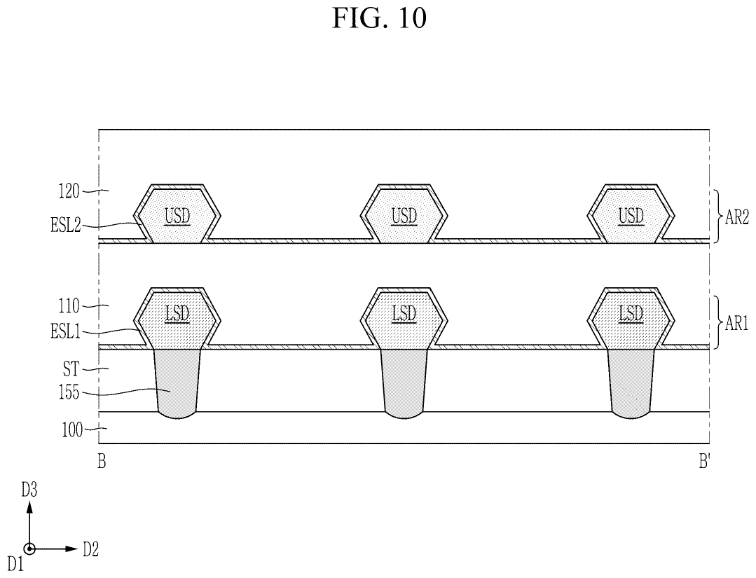

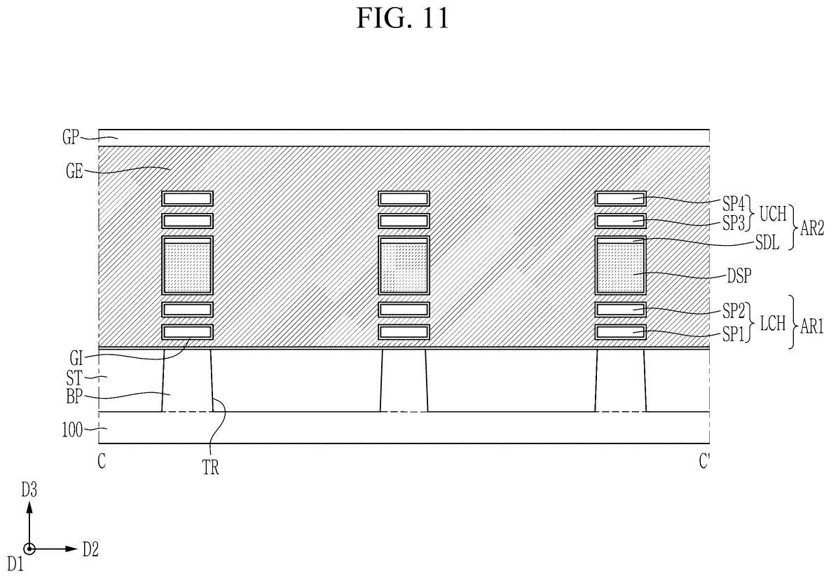

FIG. 8 is a top plan view of a semiconductor device, according to an example embodiment. FIG. 9 is a cross-sectional view of FIG. 8, taken along the lines A-A′ and D-D′, according to an example embodiment. FIG. 10 is a cross-sectional view of FIG. 8, taken along the line B-B′, according to an example embodiment. FIG. 11 is a cross-sectional view of FIG. 8, taken along the line C-C′, according to an example embodiment.

Referring to FIGS. 8 to 11, a semiconductor device in which a first active region AR1 and a second active region AR2 may be sequentially stacked on a substrate 100 may be provided.

First sacrificial layers and first active layers may be alternately stacked on the substrate 100. An intermediate insulating structure DSP and a dummy channel pattern SDL may be stacked on the first sacrificial layers and the first active layers. Second sacrificial layers and second active layers may be stacked on the dummy channel pattern SDL.

The substrate 100 may be a semiconductor substrate containing silicon (Si), germanium (Ge), silicon germanium (SiGe), or the like, or a compound semiconductor substrate. For example, the substrate 100 may be a silicon (Si) substrate.

According to an example, the first and second sacrificial layers may contain materials that may be different from those of the first and second active layers. The first sacrificial layer and the second sacrificial layer may include silicon (Si), germanium (Ge), or silicon-germanium (SiGe), and the first active layer and the second active layer may include silicon (Si), germanium (Ge), silicon-germanium (SiGe). For example, the first sacrificial layer and the second sacrificial layer may include silicon-germanium (SiGe), and the first active layer and the second active layer may include silicon (Si).

The stacked first and second sacrificial layers, the first and second active layers, the intermediate insulating structure DSP, and the dummy channel pattern SDL may be patterned to form a stacked pattern. For example, the stacked pattern may be formed by forming a hard mask pattern on the uppermost second active layer and etching the stacked layers on the substrate 100 using the hard mask pattern as an etching mask. While the stacked pattern is being formed, an upper portion of the substrate 100 may be patterned to form a trench TR defining a bottom pattern BP. The stacked pattern may have a bar shape extending in the first direction D1.

The stacked pattern may include a lower stacked pattern above the bottom pattern BP, and an upper stacked pattern above the lower stacked pattern. The lower stacked pattern may include the first sacrificial layers and the first active layers that may be alternately stacked. The upper stacked pattern may include the second sacrificial layers and the second active layers that may be alternately stacked.

A device isolation layer ST that fills the trench may be formed on the substrate 100. For example, an insulation layer covering the bottom patterns BP and the stacked patterns may be formed over the entire surface of substrate 100. The device isolation layer ST may be formed by recessing the insulation layer until stacked patterns STP may be exposed.

A plurality of sacrificial patterns may be formed across the stacked pattern. Each sacrificial pattern may be formed in the form of a line extending in the second direction D2. For example, the sacrificial pattern may be formed by forming a sacrificial layer on the stacked pattern, forming a hard mask pattern on the sacrificial layer, and patterning the sacrificial layer using the hard mask pattern as an etching mask. The sacrificial layer may include amorphous silicon or polysilicon.

In addition, a preliminary capping layer and a pair of gate spacers GS may be formed on both side surfaces of the sacrificial pattern in the first direction D1, respectively.

Using the sacrificial patterns, the preliminary capping layers, and the gate spacers GS as etching masks, at least a portion of the stacked pattern and bottom pattern BP may be etched to form recesses, and a dummy source/drain pattern 155, a lower source/drain pattern LSD, a first layer interlayer stop film ESL1, a first interlayer insulating layer 110, an upper source/drain pattern USD, a second interlayer stop film ESL2, and a second interlayer insulating layer 120 may be sequentially formed in the recesses.

The preliminary capping layer may be removed to expose the sacrificial pattern, and the exposed sacrificial pattern may be removed to form first recesses. For example, sacrificial pattern removal may be accomplished by wet etching using an etching solution that selectively etches polysilicon. As the sacrificial pattern may be removed, the first and second sacrificial layers may be exposed.

An etching process may be performed to selectively etch the exposed first and second sacrificial layers such that only the first and second sacrificial layers may be removed while remaining the first and second semiconductor patterns SP1 and SP2.

For example, the etching process of the first and second sacrificial layers may have a high etch rate for silicon germanium (SiGe). For example, the etching process may have a high etch rate for silicon germanium (SiGe) having a germanium (Ge) concentration greater than ten (10) atomic percentage (at %). However, embodiments of the present disclosure are not limited thereto, and the germanium (Ge) concentration may vary according to design constraints.

According to an example, a gate pattern GE may be formed in a region where the sacrificial pattern and the first and second sacrificial layers may be removed.

A gate insulation layer GI may be conformally formed within the region where the sacrificial pattern and the first and second sacrificial layers may be removed.

The gate pattern GE may be formed on the gate insulation layer GI. The gate pattern GE may be formed by forming a lower gate pattern LGE including first to third gate portions PO1 to PO3 between first semiconductor patterns SP1 and forming an upper gate pattern UGE including fourth to sixth gate portions PO4 to PO6 between second semiconductor patterns SP2.

The gate pattern GE may be recessed such that the height thereof may be reduced. The gate capping pattern GP may be formed on the recessed gate pattern GE. A planarization process may be performed on the gate capping pattern GP such that an upper surface of the gate capping pattern GP may be coplanar with an upper surface of the second interlayer insulating layer 120.

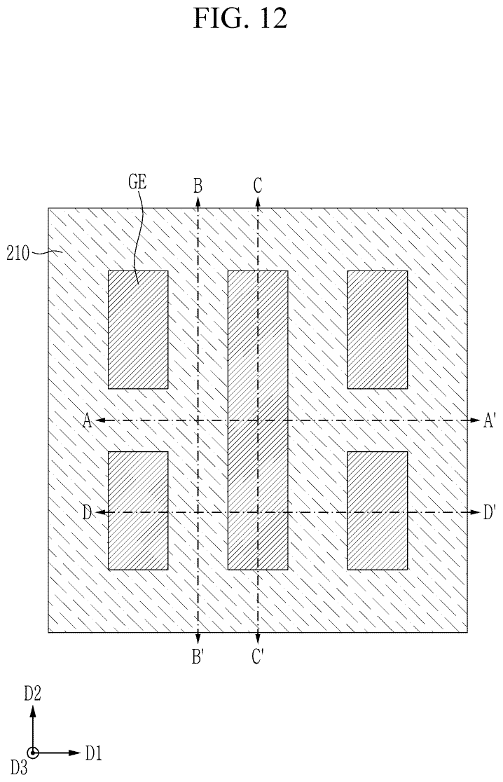

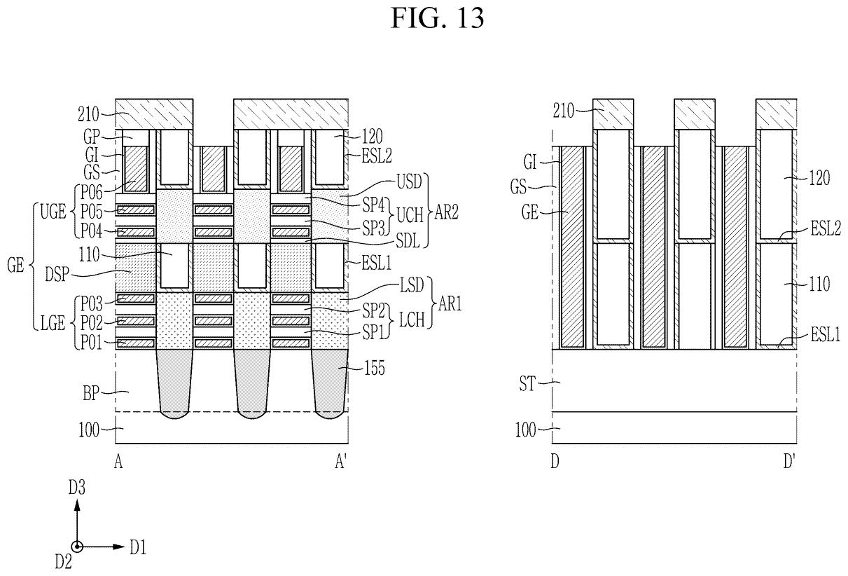

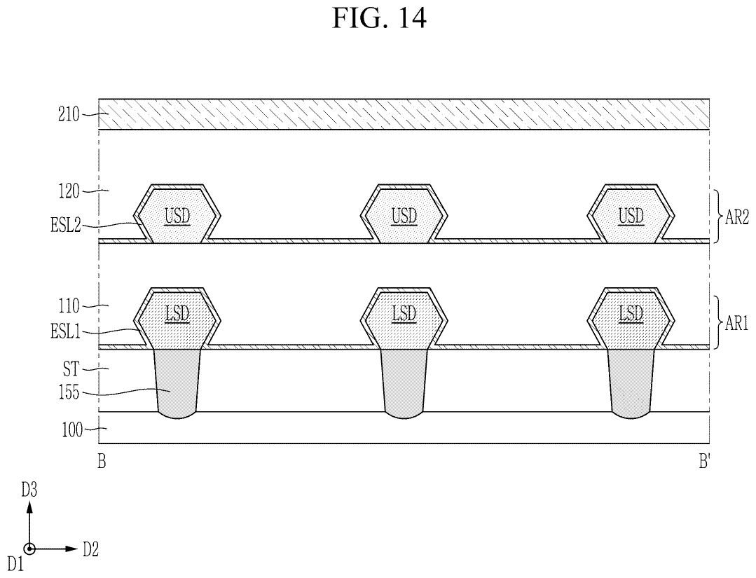

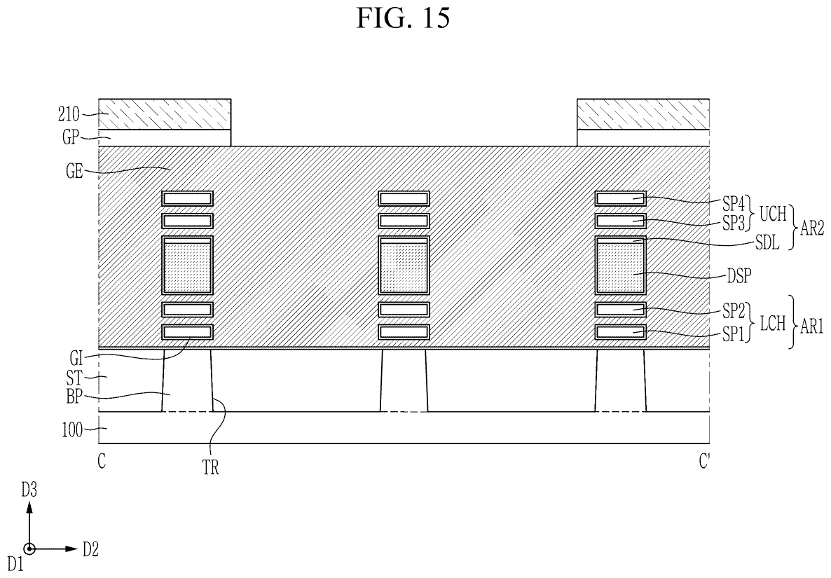

FIG. 12 is a top plan view of a semiconductor device, according to an example embodiment. FIG. 13 is a cross-sectional view of FIG. 12, taken along the lines A-A′ and D-D′, according to an example embodiment. FIG. 14 is a cross-sectional view of FIG. 12, taken along the line B-B′, according to an example embodiment. FIG. 15 is a cross-sectional view of FIG. 12, taken along the line C-C′, according to an example embodiment.

Referring to FIGS. 12 to 15, a first hard mask pattern 210 may be formed on the second interlayer insulating layer 120 and the gate capping pattern GP. For example, the first hard mask pattern 210 may be formed to cover upper surfaces of the second interlayer insulating layer 120 and the gate capping pattern GP.

The first hard mask pattern 210 may be used as an etching mask to etch the gate capping pattern GP to form the first recess exposing the gate pattern GE. For example, the first recess may be formed in a form that extends along the second direction D2 on the gate pattern GE.

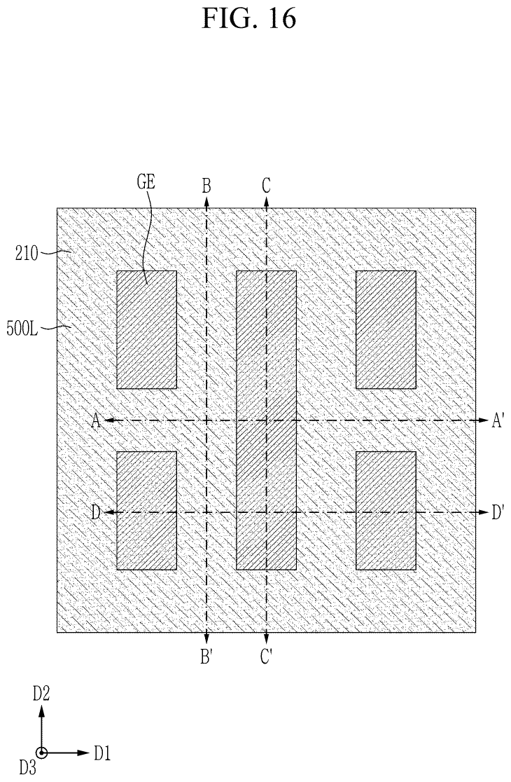

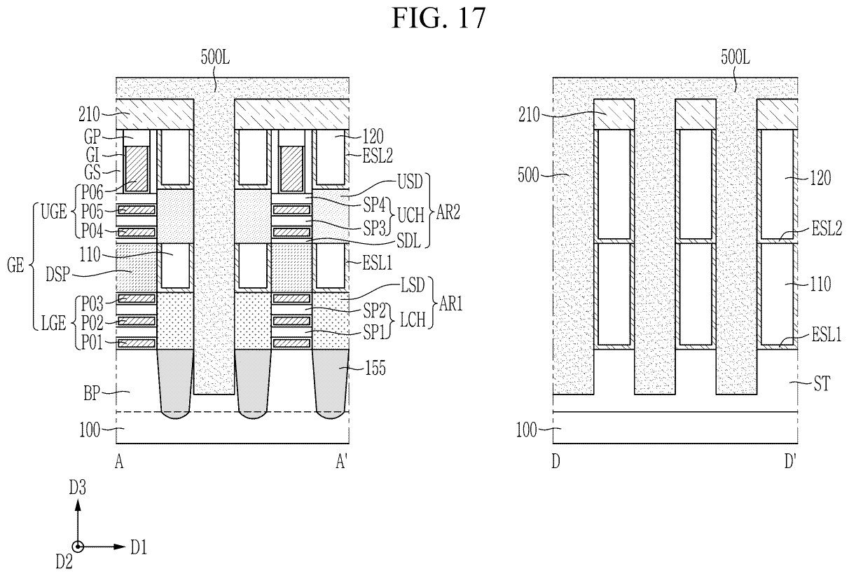

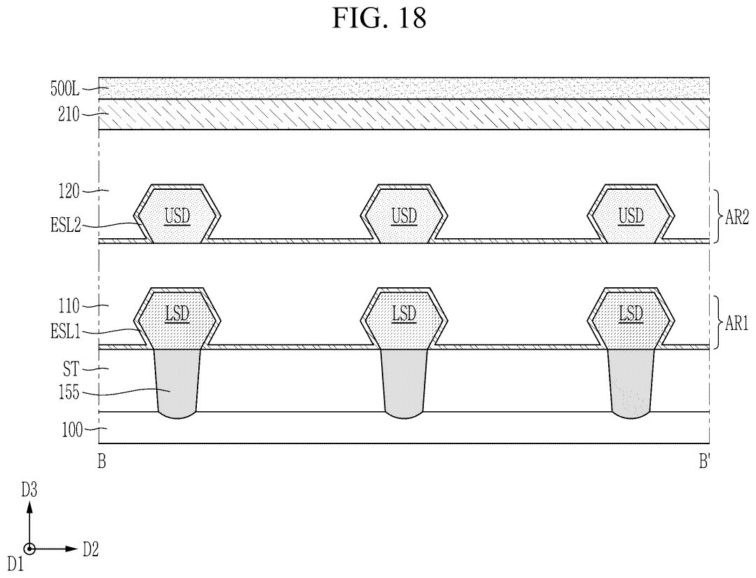

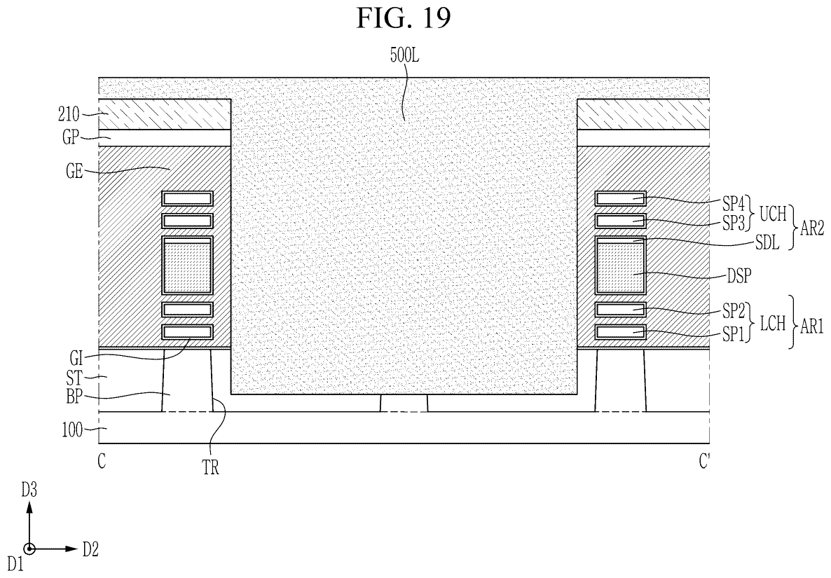

FIG. 16 is a top plan view of the semiconductor device, according to an example semiconductor device top plan view. FIG. 17 is a cross-sectional view of FIG. 16, taken along the lines A-A′ and D-D′, according to an example embodiment. FIG. 18 is a cross-sectional view of FIG. 16, taken along the line B-B′, according to an example embodiment. FIG. 19 is a cross-sectional view of FIG. 16, taken along the line C-C′, according to an example embodiment.

Referring to FIGS. 16 to 19, the gate pattern GE exposed by the first recess may be removed. In this case, an upper channel pattern UCH and a lower channel pattern LCH exposed as the gate pattern GE may also be removed.

According to an example, parts of the bottom pattern BP and the device isolation layer ST disposed below the gate pattern GE may be removed together with the gate pattern GE to form a second recess. A level of a lower end portion of the second recess may be lower than a level of a lower end portion of the gate pattern GE and may be higher than a level of an upper end portion of the substrate 100.

According to an example, a separator 500L may be formed by filling an insulating material in the second recess. The separator 500L may be formed to cover an upper surface of the first hard mask pattern 210.

For example, the separator 500L may include an insulating material. For example, the separator 500L may include silicon oxide (SiO₂), silicon nitride (SiN), silicon oxynitride (SiON), a high dielectric constant (high-k) material having a higher dielectric constant than silicon oxide (SiO₂), or a combination thereof, and may include silicon nitride (SiN).

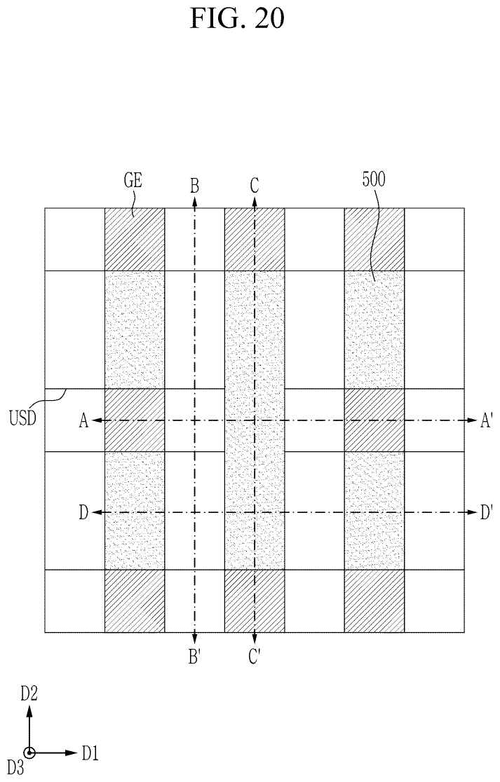

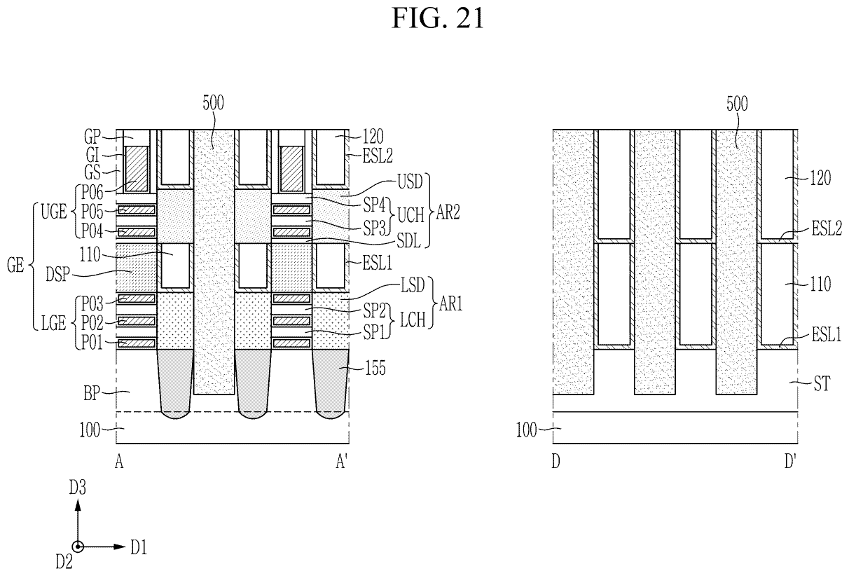

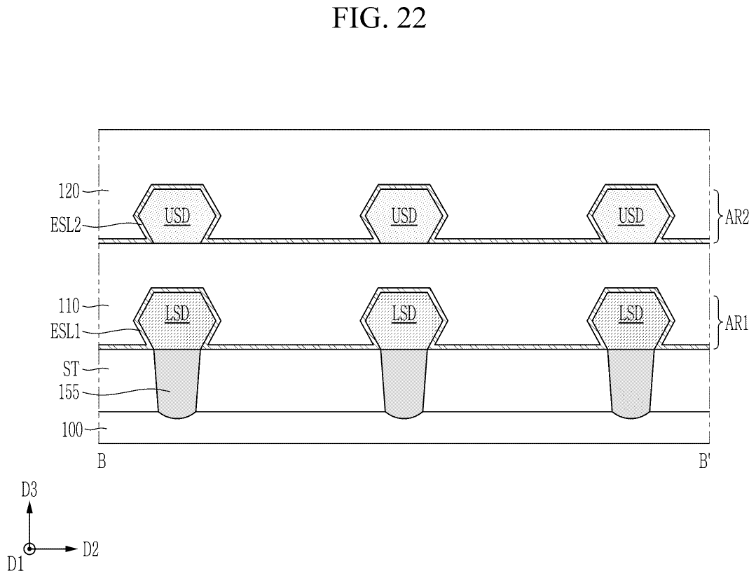

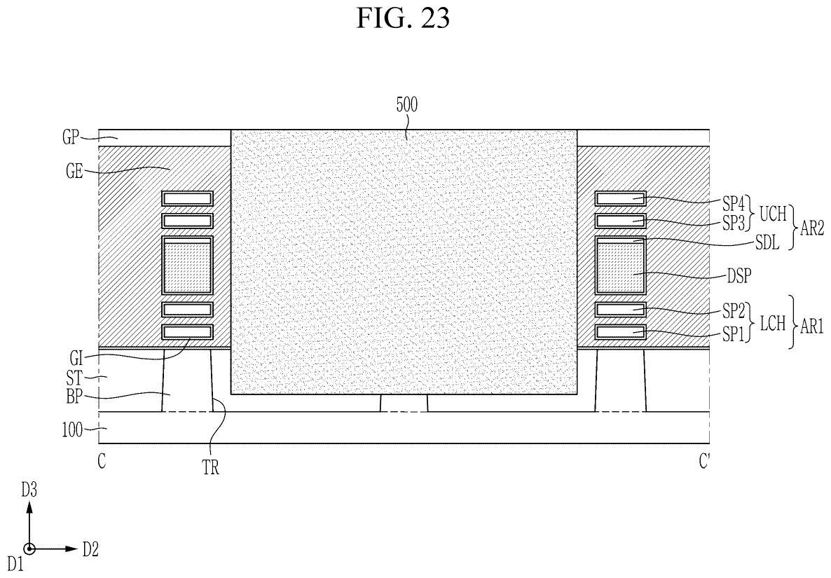

FIG. 20 is a top plan view of the semiconductor device, according to an example embodiment. FIG. 21 is a cross-sectional view of FIG. 20, taken along the lines A-A′ and D-D′, according to an example embodiment. FIG. 22 is a cross-sectional view of FIG. 20, taken along the line B-B′, according to an example embodiment. FIG. 23 is a cross-sectional view of FIG. 20, taken along the line C-C′, according to an example embodiment.

Referring to FIGS. 20 to 23, the separation pattern 500 may be formed by planarizing the separator 500L until the gate capping pattern GP may be exposed. The planarization process may be performed using an etch back or a chemical mechanical polishing (CMP) process.

While the planarization process is performed, the first hard mask pattern 210 may also be removed. For example, while the planarization process is performed, the separator 500L on the first hard mask pattern 210 may be removed and the first hard mask pattern 210 may be removed. In this case, the separator 500L disposed between the first hard mask patterns 210 spaced apart in the second direction D2 may also be removed.

As described, as the separation pattern 500 may be formed at a position from which the gate pattern GE may be removed, a width of the separation pattern 500 in the first direction D1 may be similar to or substantially the same as a width of the gate pattern GE in the first direction D1.

According to an example, the separation pattern 500 may extend in the third direction D3. For example, an upper surface of the separation pattern 500 may be coplanar with an upper surface of the gate capping pattern GP. A level of a lower end portion of the separation pattern 500 may be lower than a level of a lower end portion of the gate pattern GE.

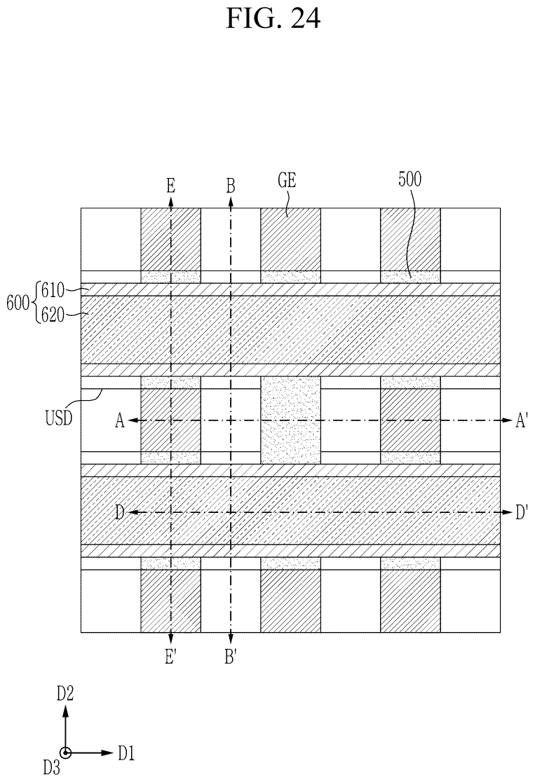

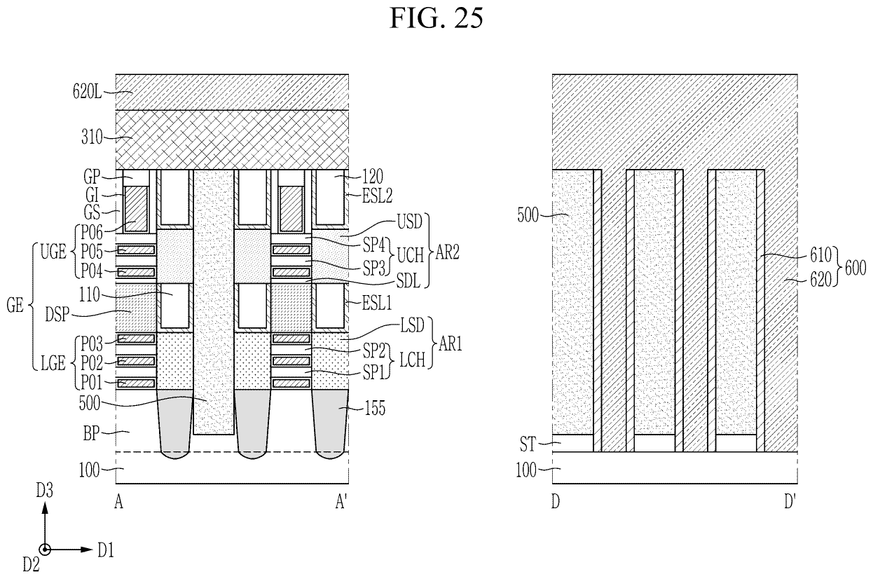

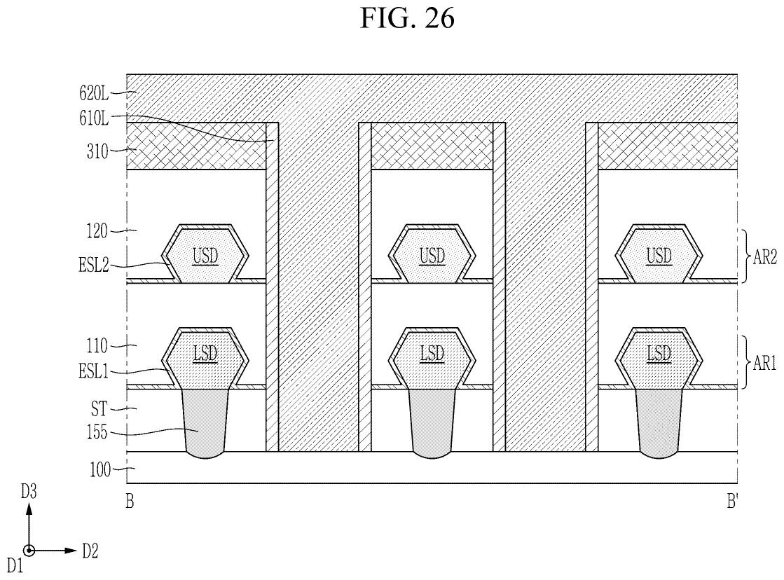

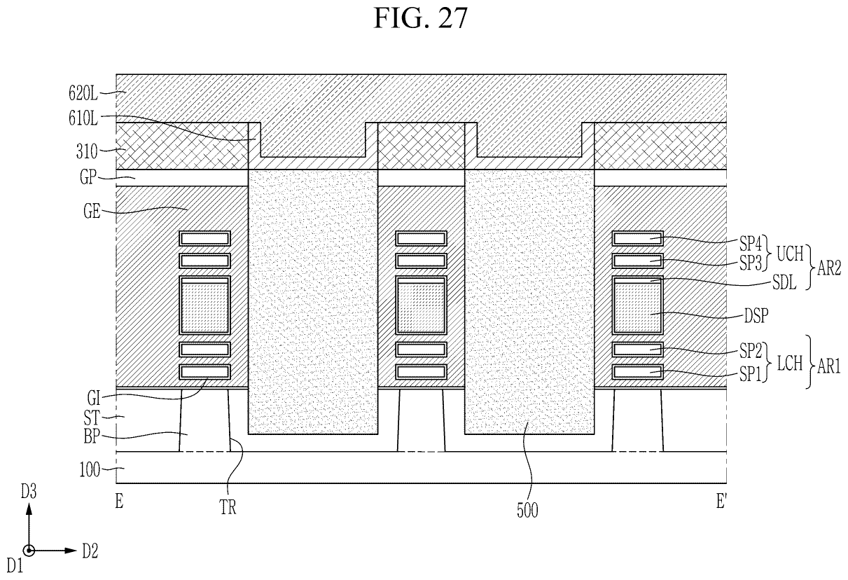

FIG. 24 is a top plan view of the semiconductor device, according to an example embodiment. FIG. 25 is a cross-sectional view of FIG. 24, taken along the lines A-A′ and D-D′, according to an example embodiment. FIG. 26 is a cross-sectional view of FIG. 24, taken along the line B-B′, according to an example embodiment. FIG. 27 is a cross-sectional view of FIG. 24, taken along the line C-C′, according to an example embodiment.

Referring to FIGS. 24 to 27, an insulation liner layer 610L and a gap-fill insulation layer 620L may be formed between one lower channel pattern LCH and one upper channel pattern UCH and another lower channel pattern LCH and another upper channel pattern UCH in the second direction D2.

According to an example, a second hard mask pattern 310 may be formed on a second interlayer insulating layer 120, and portions of the first interlayer insulating layer 110 and the second interlayer insulating layer 120 may be etched using the second hard mask pattern 310 as an etching mask. The insulation liner layer 610L may be conformally applied to a region where a portion of the first interlayer insulating layer 110 and a portion of the second interlayer insulating layer 120 have been removed, and then a space between the insulation liner layers 610L may be filled with the gap-fill insulation layer 620L.

For example, the gap-fill insulation layer 620L may include silicon oxide (SiO₂) and the insulation liner layer 610L may include silicon nitride (SiN).

According to an example, the insulation liner layer 610L may be conformally applied to an upper surface of the second hard mask pattern 310, a side surface of the second hard mask pattern 310, and exposed side surfaces of the first interlayer insulating layer 110 and second interlayer insulating layer 120. The gap-fill insulation layer 620L may cover an upper surface of the insulation liner layer 610L while filling the space between the insulation liner layers 610L.

According to an example, while the first interlayer insulating layer 110 and the second interlayer insulating layer 120 may be etched, the separation pattern 500 disposed between the gate patterns GE in the second direction D2 may be hardly etched. Accordingly, the insulation liner layer 610L and the gap-fill insulation layer 620L may not be formed between the gate patterns GE in the second direction D2.

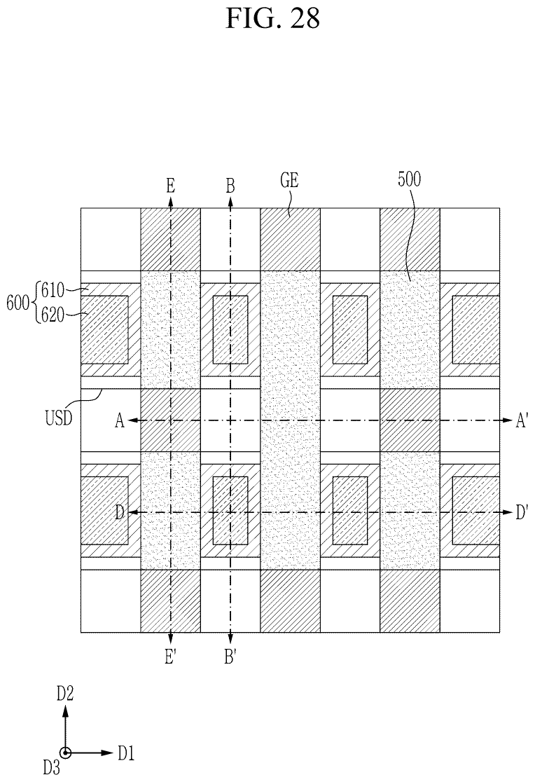

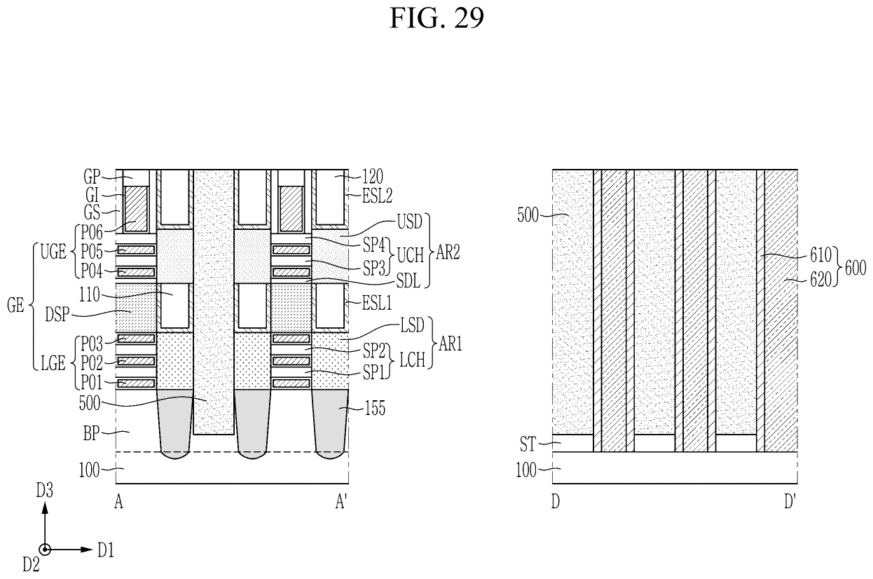

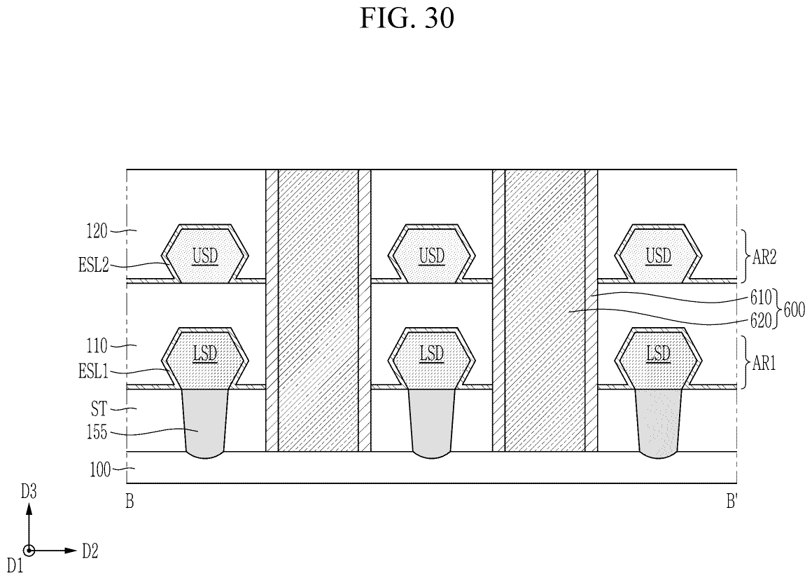

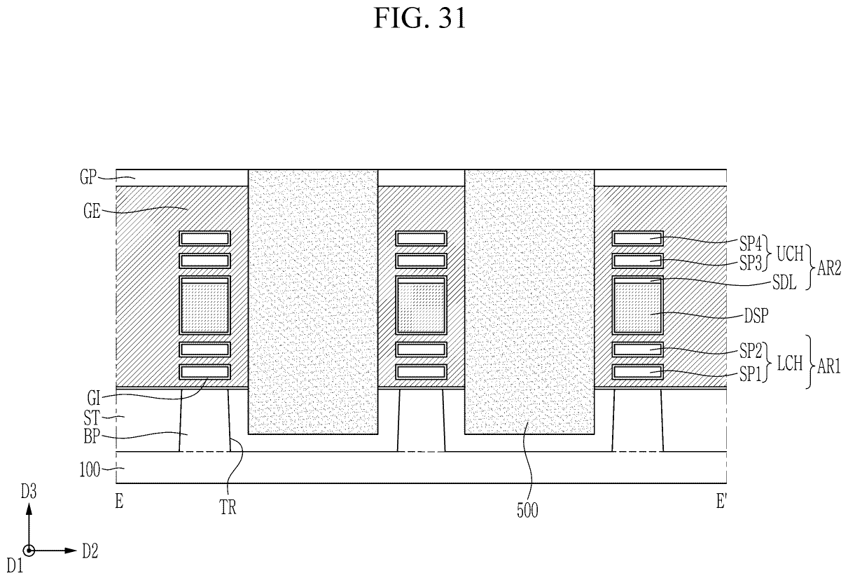

FIG. 28 is a top plan view of the semiconductor device, according to an example embodiment. FIG. 29 is a cross-sectional view of FIG. 28, taken along the lines A-A′ and D-D′, according to an example embodiment. FIG. 30 is a cross-sectional view of FIG. 28, taken along the line B-B′, according to an example embodiment. FIG. 31 is a cross-sectional view of FIG. 28, taken along the line E-E′, according to an example embodiment.

Referring to FIGS. 28 to 31, the gate cut pattern 600 may be formed by planarizing the insulation liner layer 610L and the gap-fill insulation layer 620L until the gate capping pattern GP may be exposed. The planarization process may be performed using an etch back or a chemical mechanical polishing (CMP) process.

While the planarization process is performed, the second hard mask pattern 310 may also be removed. For example, while the planarization process is performed, the gap-fill insulation layer 620L and the insulation liner layer 610L may be sequentially removed and the second hard mask pattern 310 may be removed.

Accordingly, the gate cut pattern 600 may be formed between one lower channel pattern LCH and one upper channel pattern UCH and another lower channel pattern LCH and another upper channel pattern UCH in the second direction D2.

According to an example, as the separation pattern 500 may be disposed between the gate patterns GE in the second direction D2, the gate cut pattern 600 may not be formed between the gate pattern GE in the second direction D2.

According to an example, the gate cut pattern 600 may extend in the third direction D3. For example, an upper surface of the gate cut pattern 600 may be coplanar with an upper surface of the second interlayer insulating layer 120. A level of a lower end portion of the gate cut pattern 600 may be substantially the same as a level of an upper surface of the substrate 100.

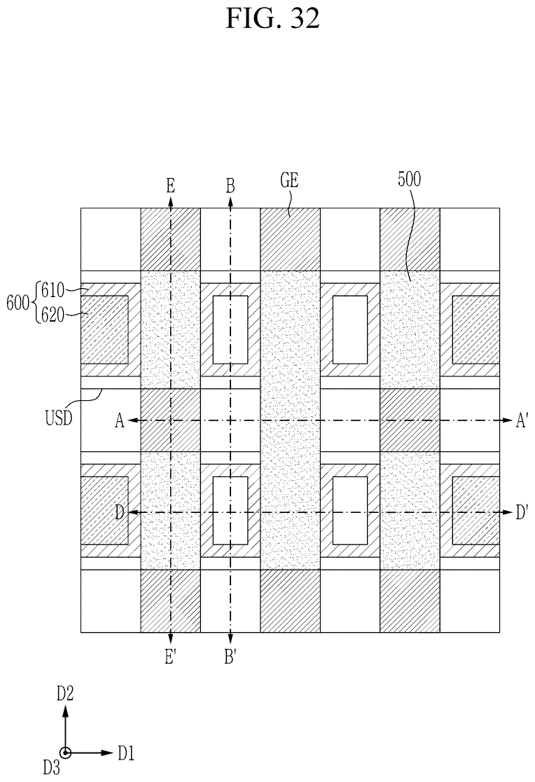

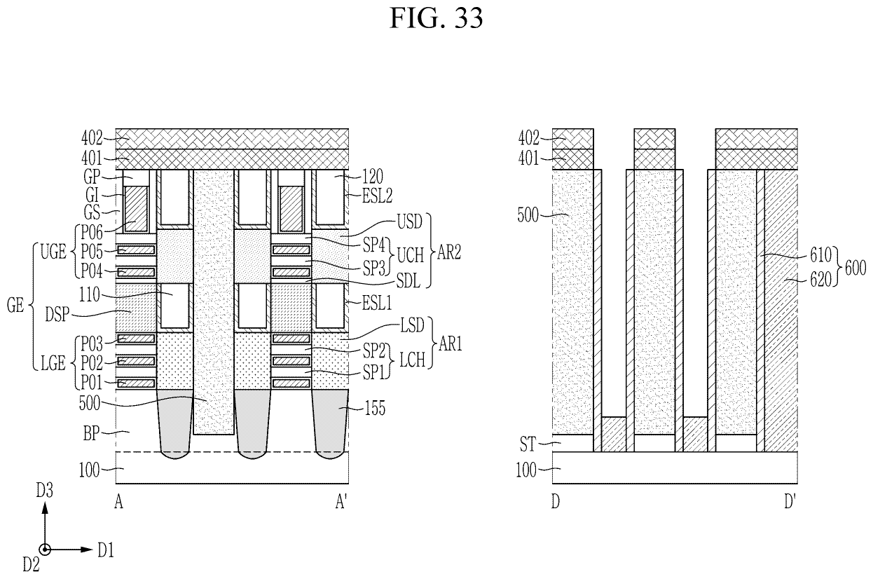

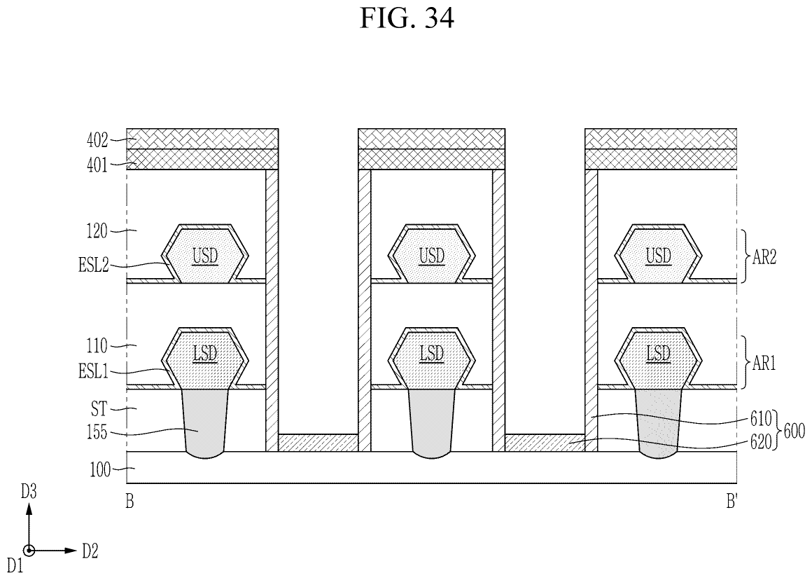

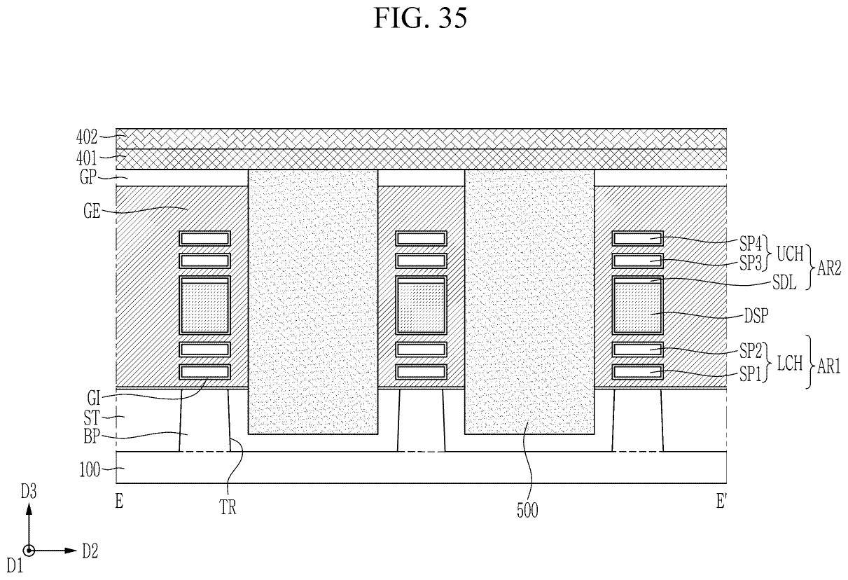

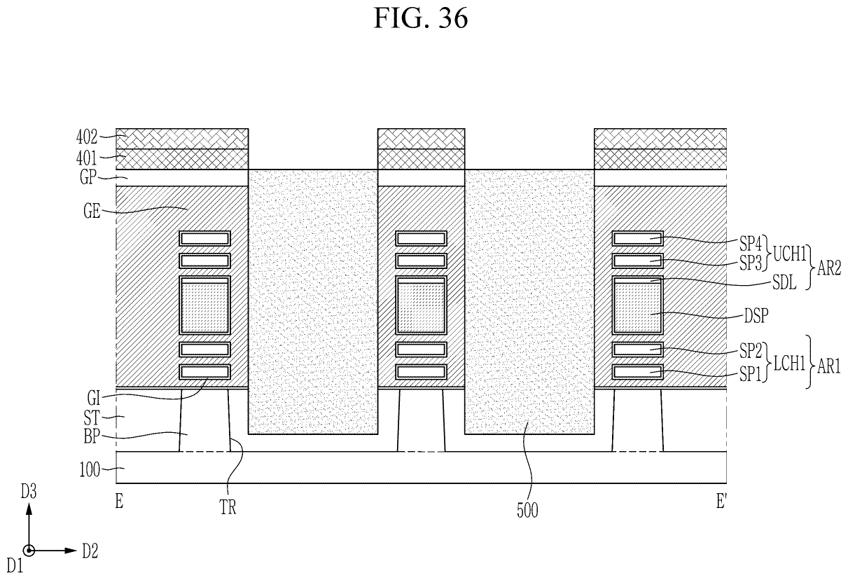

FIG. 32 is a top plan view of the semiconductor device, according to an example embodiment. FIG. 33 is a cross-sectional view of FIG. 32, taken along the lines A-A′ and D-D′, according to an example embodiment. FIG. 34 is a cross-sectional view of FIG. 32, taken along the line B-B′, according to an example embodiment. FIG. 35 is a cross-sectional view of FIG. 32, taken along the line E-E′, according to an example embodiment. FIG. 36 is a cross-sectional view of FIG. 32, taken along the line E-E′, according to some example embodiments.

Referring to FIGS. 32 to 36, a recess may be formed by etching the gap-fill insulation layer 620 in the gate cut pattern 600 at a position where the through via 650 may be formed.

According to an example, a third hard mask pattern 401 and a fourth hard mask pattern 402 may be formed on the second interlayer insulating layer 120. Referring to FIG. 35, depending on examples, the third hard mask pattern 401 and the fourth hard mask pattern 402 may be formed in a region excluding the region where the through via 650 may be formed. For example, the third hard mask pattern 401 and the fourth hard mask pattern 402 may be formed to cover the gate capping pattern GP and the separation pattern 500. However, embodiments of the present disclosure are not limited to thereto, and the shape or position of the third hard mask pattern 401 and the fourth hard mask pattern 402 may be changed in various ways. For example, as shown in FIG. 36, the third hard mask pattern 401 and the fourth hard mask pattern 402 may be formed to cover the gate capping pattern GP and not cover the separation pattern 500.

For example, the third hard mask pattern 401 may include silicon oxide (SiO₂), and the fourth hard mask pattern 402 may include a metal layer or a metal nitride layer.

According to an example, the insulation liner 610 and the separation pattern 500 may include a material having etch selectivity with respect to the gap-fill insulation layer 620. For example, the gap-fill insulation layer 620 may include silicon oxide (SiO₂), the insulation liner 610 may include silicon nitride (SiN), and the separation pattern 500 may include silicon nitride (SiN).

According to an example, the gap-fill insulation layer 620 of the gate cut pattern 600 may be etched using the third hard mask pattern 401 and the fourth hard mask pattern 402 as etching masks. In this case, the insulation liner 610 may not be etched.

In addition, while the etching process is carried out, the separation pattern 500 may not be etched. For example, even when the third hard mask pattern 401 and the fourth hard mask pattern 402 cover the gate capping pattern GP and do not cover the separation pattern 500, the separation pattern 500 may not be etched while the etching process for the gap-fill insulation layer 620 may be carried out.

According to an example, at least a portion of the gap-fill insulation layer 620 may be removed during the etching process. In this case, the gap-fill insulation layer 620 may not be completely removed. For example, at least a portion of the gap-fill insulation layer 620 may remain between the separation patterns 500 in the first direction D1.

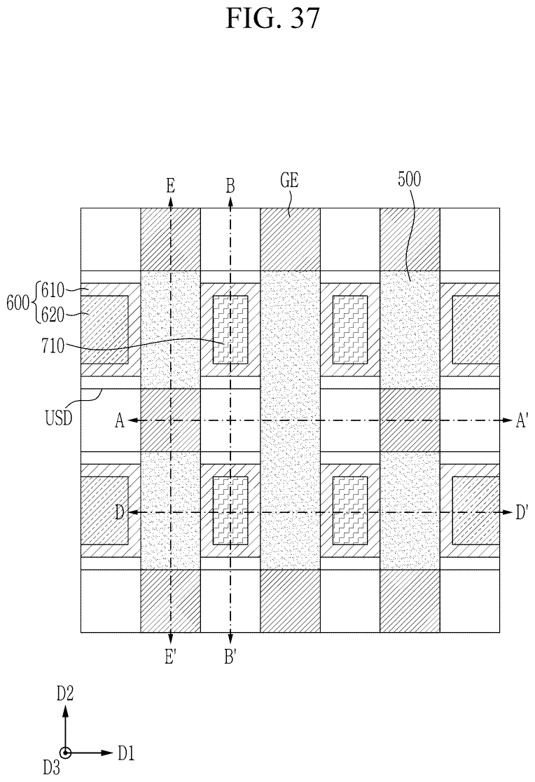

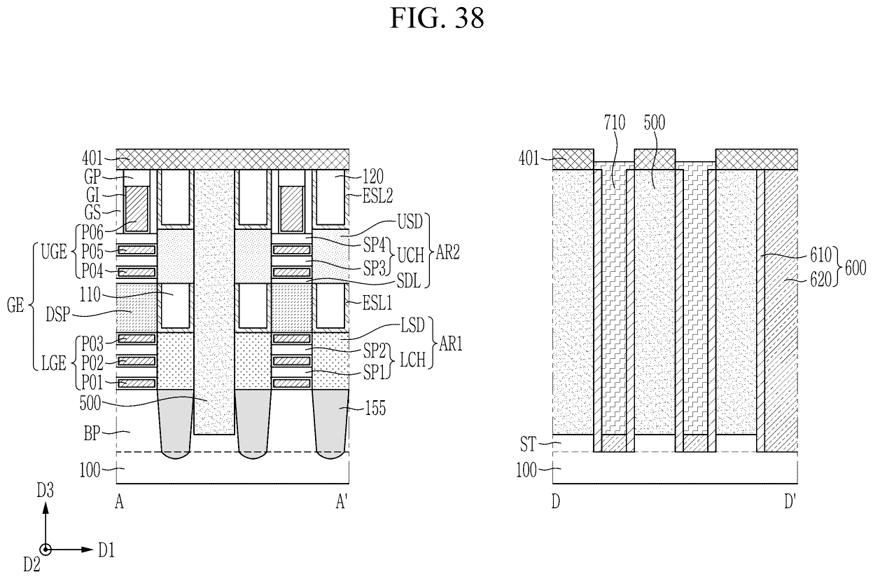

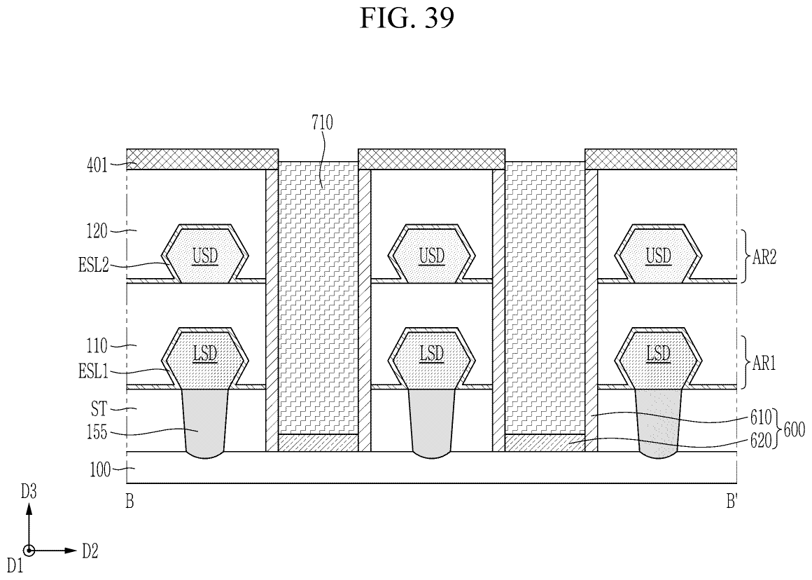

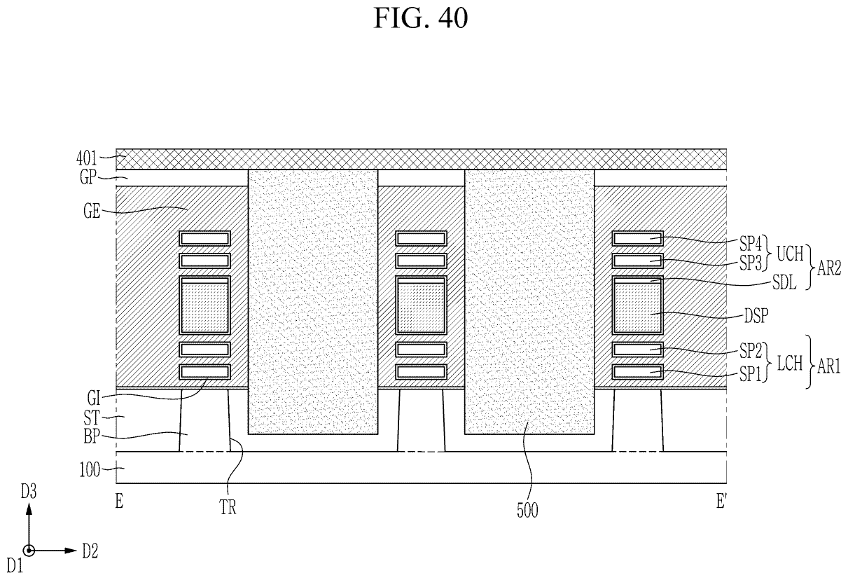

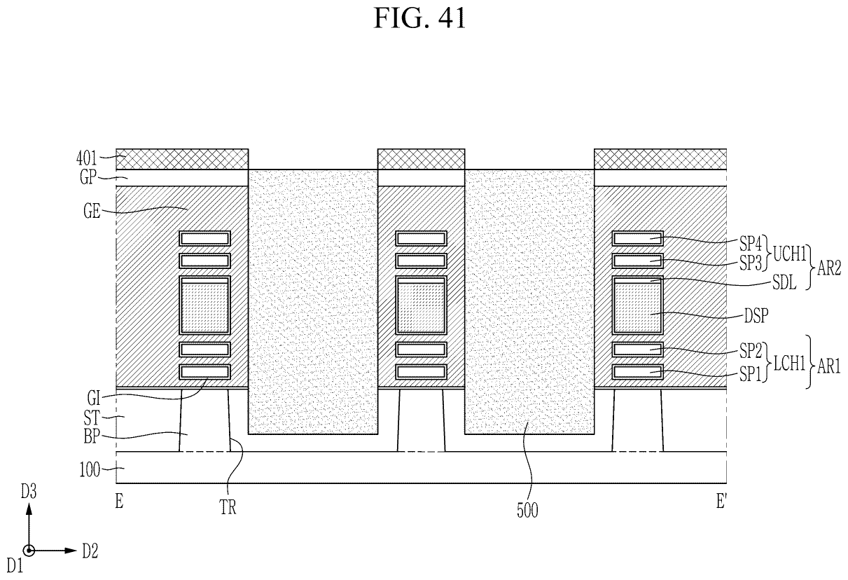

FIG. 37 is a top plan view of the semiconductor device, according to an example embodiment. FIG. 38 is a cross-sectional view of FIG. 37, taken along the lines A-A′ and D-D′, according to an example embodiment. FIG. 39 is a cross-sectional view of FIG. 37, taken along the line B-B′, according to an example embodiment. FIG. 40 is a cross-sectional view of FIG. 37, taken along the line E-E′, according to an example embodiment. FIG. 41 is a cross-sectional view of FIG. 37, taken along the line E-E′, according to some example embodiments.

Referring to FIGS. 37 to 41, a passivation layer 710 may be formed in a region where the gap-fill insulation layer 620 may be removed, and the fourth hard mask pattern 402 may be removed.

According to an example, the passivation layer 710 may be formed in the region from which the gap-fill insulation layer 620 may be removed in order to protect a region exposed by removing the gap-fill insulation layer 620. The passivation layer 710 may fill the region where the gap-fill insulation layer 620 may be removed. For example, the passivation layer 710 may include a carbon material. The fourth hard mask pattern 402 may be removed. In some examples, forming the passivation layer 710 in the region where the gap-fill insulation layer 620 may be removed may be omitted. In this case, a through via 650 may be formed in the region where the gap-fill insulation layer 620 may be removed.

According to an example, as the fourth hard mask pattern 402 may be removed, as shown in FIG. 40, the third hard mask pattern 401 may remain on the gate capping pattern GP and the separation pattern 500. According to some examples, as shown in FIG. 41, the third hard mask pattern 401 remains on the gate capping pattern GP, and the upper surface of the separation pattern 500 may be exposed.

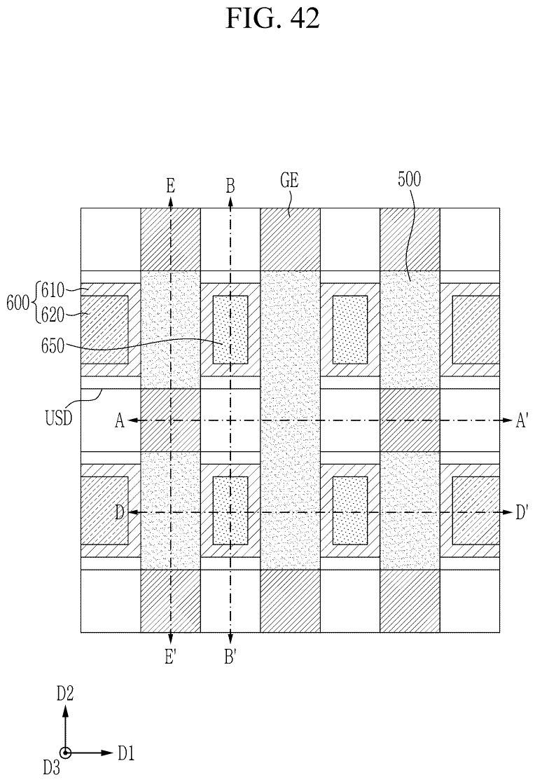

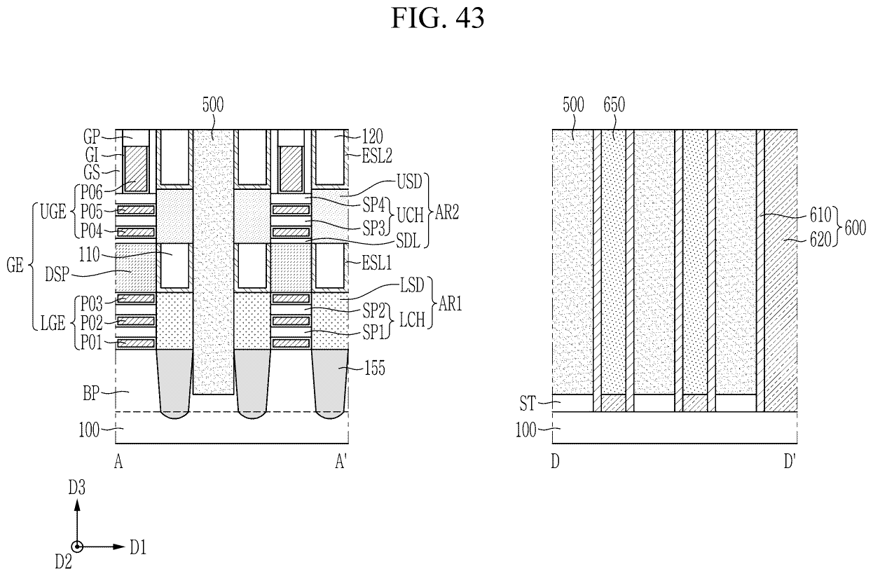

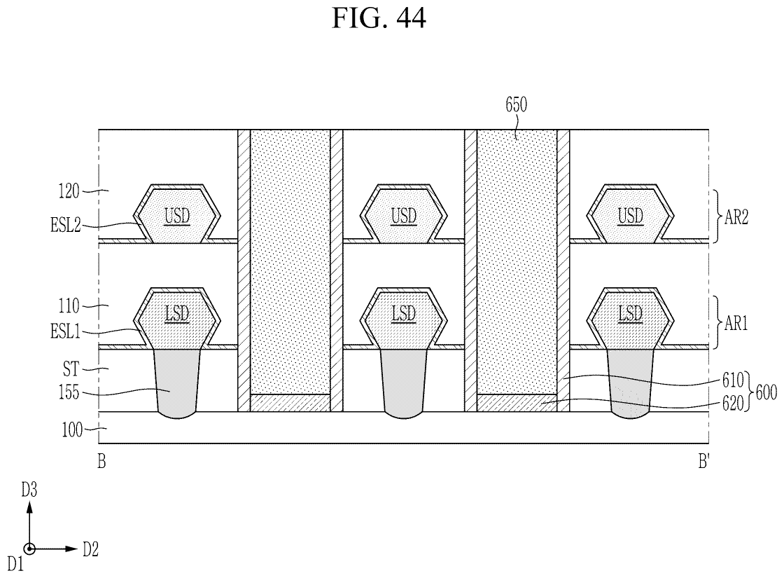

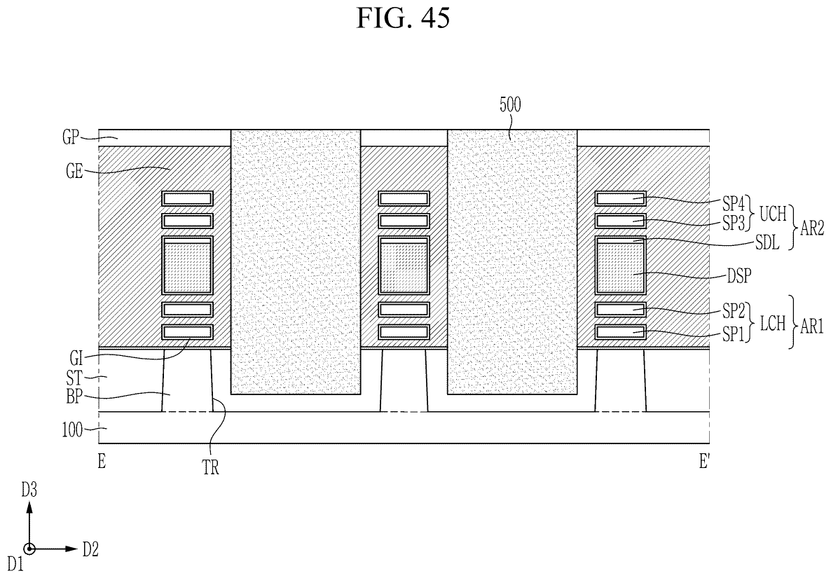

FIG. 42 is a top plan view of the semiconductor device, according to an example embodiment. FIG. 43 is a cross-sectional view of FIG. 42, taken along the lines A-A′ and D-D′, according to an example embodiment. FIG. 44 is a cross-sectional view of FIG. 42, taken along the line B-B′, according to an example embodiment. FIG. 45 is a cross-sectional view of FIG. 42, taken along the line E-E′, according to an example embodiment.

Referring to FIGS. 42 to 45, the passivation layer 710 may be removed and the through via 650 may be formed in a region from which the passivation layer 710 may be removed.

According to an example, the region from which the passivation layer 710 may be removed may be filled with a metallic material. For example, the metallic material may include aluminum (Al), copper (Cu), tungsten (W), molybdenum (Mo), titanium (Ti), tantalum (Ta), tungsten (W), nickel (Ni), cobalt (Co), platinum (Pt), a titanium nitride layer (TiN), a tantalum nitride layer (TaN), a tungsten nitride layer (WN), a nickel nitride layer (NiN), a cobalt nitride layer (CoN), a platinum nitride layer (PtN), or a combination thereof.

According to an example, the through via 650 may be formed by planarizing the metallic material until the gate capping pattern GP is exposed. The planarization process may be performed using an etch back or a chemical mechanical polishing (CMP) process.

While the planarization process is performed, the third hard mask pattern 401 may also be removed. For example, during the planarization process, after the metallic material on the third hard mask pattern 401 is removed, the third hard mask pattern 401 may be removed.

As described above, according to the present disclosure, since the gate cut pattern 600 may be formed after the separation pattern 500 may be formed between the gate patterns GE in the second direction D2, the gate cut pattern 600 may not overlap the gate pattern GE in the second direction D2. Accordingly, the through via 650 formed within the gate cut pattern 600 may not overlap the gate pattern GE in the second direction D2, and a short may be prevented from occurring between the gate patterns GE.

After that, referring back to FIGS. 6 and 7, the upper source/drain contact aCA that contacts the upper source/drain pattern USD may be formed. In some embodiments, an upper wire structure that may be connected to the upper source/drain pattern USD through the upper source/drain contact aCA may be formed. The upper wire structure may include upper wires, upper vias, and an upper insulation layer. The upper wires and the upper vias may contain a metal (according to an example, copper). The upper insulation layer may be placed between the upper wires and upper vias to insulate them. The upper insulation layer may cover the second interlayer insulating layer 120. The upper wires and the upper vias may be disposed in the upper insulation layer.

When the substrate 100 and the bottom pattern BP include a semiconductor material such as, but not limited to, silicon (Si) or the like, the silicon (Si) may be removed and replaced with an insulation substrate 101. For example, the insulation substrate 101 may include silicon oxide (SiO₂).

After that, the lower source/drain contact bCA that may be connected to the lower source/drain pattern LSD may be formed, and a lower gate contact that may be connected to the lower gate pattern LGE of the gate pattern GE may be formed.

For example, a part of the dummy source/drain pattern 155 may be removed to form a contact hole through which the lower source/drain pattern LSD may be exposed. The lower source/drain contact bCA that may be electrically connected to the lower source/drain pattern LSD while filling the contact hole may be formed.

A patterning process may be performed to remove a portion of the insulation substrate 101 or device isolation layer ST, thereby forming a contact hole through which the lower gate pattern LGE of the gate pattern GE may be exposed. In this case, the contact hole may penetrate the insulation substrate 101 or the device isolation layer ST. The lower gate contact that may be electrically connected to the lower gate pattern LGE of the gate pattern GE while filling the contact hole may be formed.

The connection portion CM that may extend from below the lower source/drain contact bCA to below the through via 650 may be formed. For example, after performing the patterning process, the connection portion CM may be formed by filling a metal to connect the lower source/drain contact bCA and the through via 650.

Although the above describes a case where the lower source/drain contact bCA, the lower gate contact, and the connection portion CM may be formed as separate processes, embodiments of the present disclosure are not limited thereto, and the lower source/drain contact bCA, the lower gate contact, and the connection portion CM may be formed simultaneously, or the lower gate contact may be formed first, and then the lower source/drain contact bCA and the connection portion CM may be formed.

The lower wire structure M1b including the lower metal layer 420 electrically connected to the lower source/drain contact bCA, the lower gate contact, and the connection portion CM, and the lower interlayer insulating layer 410 covering the lower metal layer 420 may be formed in lower end portions of the device isolation layer ST and the insulation substrate 101.

While the present disclosure has been described in connection with what is presently considered to be practical examples, it is to be understood that the present disclosure is not limited to the disclosed examples. On the contrary, it is intended to cover various modifications and equivalent arrangements included within the spirit and scope of the appended claims.

What is claimed is:

1. A semiconductor device, comprising:
a lower channel pattern and a lower source/drain pattern alternately disposed in a first direction on a substrate;
an upper channel pattern on the lower channel pattern and an upper source/drain pattern on the lower source/drain pattern;
gate patterns spaced apart in a second direction that crosses the first direction, and at least partially around the lower channel pattern and the upper channel pattern;
a separation pattern at least partially penetrating the gate patterns in a third direction that crosses the first direction and the second direction; and
a through via spaced apart by the separation pattern in the first direction, extending in the third direction, and coupled with at least one of the lower source/drain pattern or the upper source/drain pattern.

2. The semiconductor device of claim 1, wherein the through via is not between the gate patterns.

3. The semiconductor device of claim 1, wherein the lower source/drain pattern comprises a first lower source/drain pattern and a second lower source/drain pattern,
wherein the upper source/drain pattern comprises a first upper source/drain pattern and a second upper source/drain pattern,
wherein the semiconductor device further comprises a gate cut pattern between the first lower source/drain pattern and the second lower source/drain pattern in the second direction and between the first upper source/drain pattern and the second upper source/drain pattern in the second direction, and
wherein the through via is disposed in the gate cut pattern.

4. The semiconductor device of claim 3, further comprising a dummy lower source/drain pattern below the lower source/drain pattern,
wherein a level of a lower end portion of the separation pattern is higher than a level of a lower end portion of the dummy lower source/drain pattern, and
wherein a level of a lower end portion of the gate cut pattern is higher than or equal to the level of the lower end portion of the dummy lower source/drain pattern.

5. The semiconductor device of claim 3, wherein the gate cut pattern comprises a gap-fill insulation layer and an insulation liner disposed at opposite sides of the gap-fill insulation layer in the second direction.

6. The semiconductor device of claim 5, wherein the through via is in contact with the insulation liner in the second direction, and
wherein the gap-fill insulation layer at least partially overlaps the through via in the third direction below the through via.

7. The semiconductor device of claim 5, wherein the gap-fill insulation layer comprises silicon oxide (SiO₂),
wherein the insulation liner comprises silicon nitride (SiN), and
wherein the separation pattern comprises silicon nitride (SiN).

8. A semiconductor device, comprising:
an insulation substrate comprising a first side and a second side that face each other;
a lower channel pattern and a lower source/drain pattern alternately disposed in a first direction on the first side;
an upper channel pattern on the lower channel pattern and an upper source/drain pattern on the lower source/drain pattern;
gate patterns spaced apart in a second direction that crosses the first direction, and at least partially around the lower channel pattern and the upper channel pattern;
a separation pattern at least partially penetrating the gate patterns in a third direction that crosses the first direction and the second direction;
a through via spaced apart by the separation pattern in the first direction, extending in the third direction, and coupled with at least one of the lower source/drain pattern or the upper source/drain pattern; and
a lower wire structure on the second side and coupled with the through via.

9. The semiconductor device of claim 8, wherein the through via is not between the gate patterns.

10. The semiconductor device of claim 8, further comprising:
an upper source/drain contact on the upper source/drain pattern and coupled with the upper source/drain pattern; and
a lower source/drain contact below the lower source/drain pattern and coupled with the lower source/drain pattern,
wherein the upper source/drain contact and the lower source/drain contact are coupled with the through via.

11. The semiconductor device of claim 8, further comprising:
a connection portion below a lower source/drain contact and the through via, extending in the second direction, and coupling the lower source/drain contact with the through via.

12. The semiconductor device of claim 8, wherein the lower source/drain pattern comprises a first lower source/drain pattern and a second lower source/drain pattern,
wherein the upper source/drain pattern comprises a first upper source/drain pattern and a second upper source/drain pattern,
wherein the semiconductor device further comprises a gate cut pattern between the first lower source/drain pattern and the second lower source/drain pattern and between the first upper source/drain pattern and the second upper source/drain pattern in the second direction, and
wherein the through via is disposed in the gate cut pattern.

13. The semiconductor device of claim 12, further comprising a dummy lower source/drain pattern disposed below the lower source/drain pattern,
wherein a level of a lower end portion of the separation pattern is higher than a level of a lower end portion of the dummy lower source/drain pattern, and
wherein a level of a lower end portion of the gate cut pattern is higher than or equal to the level of the lower end portion of the dummy lower source/drain pattern.

14. The semiconductor device of claim 13, wherein a lower end portion of the separation pattern is separated from the lower wire structure in the third direction,
wherein the lower end portion of the gate cut pattern contacts the lower wire structure, and
wherein the lower end portion of the dummy lower source/drain pattern contacts the lower wire structure.

15. The semiconductor device of claim 12, wherein the gate cut pattern comprises a gap-fill insulation layer and an insulation liner disposed at opposite sides of the gap-fill insulation layer in the second direction.

16. The semiconductor device of claim 15, wherein the through via is in contact with the insulation liner in the second direction, and
wherein the gap-fill insulation layer at least partially overlaps the through via in the third direction below the through via.

17. The semiconductor device of claim 15, wherein the gap-fill insulation layer comprises silicon oxide (SiO₂),
wherein the insulation liner comprises silicon nitride (SiN), and
wherein the separation pattern comprises silicon nitride (SiN).

18. A semiconductor device, comprising:
a lower channel pattern and a lower source/drain pattern alternately disposed in a first direction on a substrate;
an upper channel pattern on the lower channel pattern and an upper source/drain pattern on the lower source/drain pattern;
gate patterns spaced apart in a second direction that crosses the first direction, and at least partially around the lower channel pattern and the upper channel pattern;
a gate cut pattern disposed between one of the lower source/drain pattern and one of the lower source/drain pattern and another one of the lower source/drain pattern and another one of the upper source/drain pattern in the second direction;
a separation pattern at least partially penetrating the gate patterns in a third direction that crosses the first direction and the second direction; and
a through via disposed within the gate cut pattern, extending in the third direction, and coupled with at least one of the lower source/drain pattern or the upper source/drain pattern,
wherein the separation pattern and the through via are alternately disposed along the first direction.

19. The semiconductor device of claim 18, wherein the through via is not disposed between the gate patterns.

20. The semiconductor device of claim 18, further comprising a dummy lower source/drain pattern below the lower source/drain pattern,
wherein a level of a lower end portion of the separation pattern is higher than a level of a lower end portion of the dummy lower source/drain pattern, and
wherein a level of a lower end portion of the gate cut pattern is higher than or equal to the level of the lower end portion of the dummy lower source/drain pattern.
